(19) United States
(12) Patent Application Publication
(10) Pub. No.: US 2026/0324059 A1
(43) Pub. Date: Oct. 15, 2026

(54) SEMICONDUCTOR DEVICES WITH GATE STRUCTURES HAVING GATE PROTRUSIONS AND DATA STORAGE SYSTEMS INCLUDING THE SAME

(71) Applicant: SAMSUNG ELECTRONICS CO., LTD., Suwon-si (KR)

(72) Inventors: Seongpil CHANG, Suwon-si (KR); Seahoon LEE, Suwon-si (KR); Sejun PARK, Suwon-si (KR)

(73) Assignee: SAMSUNG ELECTRONICS CO., LTD., Suwon-si (KR)

(21) Appl. No.: 19/629,602

(22) Filed: Mar. 26, 2026

(30) Foreign Application Priority Data
Apr. 11, 2025 (KR) 10-2025-0047577

(51) Int. Cl. H10D 84/83; H10B 41/40; H10B 43/40; H10D 62/13; H10D 64/27; H10W 10/17

(52) U.S. Cl. CPC H10D 84/83125; H10B 41/40; H10B 43/40; H10D 62/151; H10D 64/519; H10W 10/17

(57) ABSTRACT

A semiconductor device includes a substrate, a first gate structure and a second gate structure on the substrate and spaced apart from each other in a first direction, a first source/drain region on one side of the first gate structure, a second source/drain region on one side of the second gate structure, and a common source/drain region between the first gate structure and the second gate structure, where the common source/drain region includes a body portion having a first length in the first direction between the first gate structure and the second gate structure and a first width in a second direction intersecting the first direction and a protrusion protruding from one side of the body portion and having a second length in the first direction that is less than the first length.

### CROSS-REFERENCE TO RELATED APPLICATION

This application is based on and claims priority to Korean Patent Application No. 10-2025-0047577, filed on Apr. 11, 2025, in the Korean Intellectual Property Office, the disclosure of which is incorporated herein by reference in its entirety.

### BACKGROUND

The present disclosure relates to a semiconductor device and a data storage system including the same.

A semiconductor device able to store high-capacity data in a data storage system requiring data storage has been required. Accordingly, a method for increasing data storage capacity of a semiconductor device has been researched. For example, as a method for increasing data storage capacity of a semiconductor device, a semiconductor device including memory cells disposed three-dimensionally, instead of memory cells disposed two-dimensionally, has been suggested. Also, circuit elements driving memory cells may include complementary metal-oxide-semiconductor (CMOS) transistors.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a semiconductor device which may be implemented such that transistors are connected in series and parallel and share a source or drain region, and may prevent current concentration when a contact region in a shared active region protrudes.

One or more example embodiments provide a semiconductor device in which a gate structure may be disposed such that a current is evenly distributed in peripheral circuit elements driven by a large/high voltage among peripheral circuit structures driving a cell structure.

Additional aspects will be set forth in part in the description which follows and, in part, will be apparent from the description, or may be learned by practice of the presented embodiments.

According to an aspect of an example embodiment, a semiconductor device may include a substrate, a first gate structure and a second gate structure on the substrate and spaced apart from each other in a first direction, a first source/drain region on one side of the first gate structure, a second source/drain region on one side of the second gate structure, and a common source/drain region between the first gate structure and the second gate structure, where the common source/drain region includes a body portion having a first length in the first direction between the first gate structure and the second gate structure and a first width in a second direction intersecting the first direction and a protrusion protruding from one side of the body portion and having a second length in the first direction that is less than the first length, and at least one of the first gate structure and the second gate structure includes a base region between the body portion and at least one of the first source/drain region and the second source/drain region and a gate protrusion protruding from the base region toward the protrusion.

According to an aspect of an example embodiment, a semiconductor device may include a cell structure including cell gate electrodes, channel structures penetrating the cell gate electrodes, and contact plugs connected to the cell gate electrodes, and a peripheral circuit structure connected to the cell structure, and including a substrate including a first element region and a second element region, first circuit elements in the first element region and having a first conductivity-type, second circuit elements in the first element region and having a second conductivity-type different from the first conductivity-type, third circuit elements in the second element region and having the first conductivity-type, and fourth circuit elements in the second element region and having the second conductivity-type, where each of the first circuit elements and the second circuit elements includes a gate structure including a gate dielectric layer on the substrate, and a gate electrode on the gate dielectric layer, each of the fourth circuit elements includes a first gate structure and a second gate structure on the substrate and spaced apart from each other in a first direction, individual source/drain regions on external sides of the first gate structure and the second gate structure in the first direction, and a common source/drain region between the first gate structure and the second gate structure, the common source/drain region includes a body portion aligned with the individual source/drain regions in the first direction and a protrusion protruding from one side of the body portion between the first gate structure and the second gate structure, and each of first gate structure and the second gate structure includes a gate protrusion protruding toward the protrusion in the first direction and spaced apart from the protrusion in the first direction.

According to an aspect of an example embodiment, a data storage system may include a semiconductor storage device including a first substrate structure including a substrate, first circuit elements on the substrate and driven by a first drive voltage and second circuit elements on the substrate driven by a second drive voltage greater than the first drive voltage, a second substrate structure including channel structures and gate electrodes, and an input/output pad connected to the first circuit elements and the second circuit elements, and a controller connected to the semiconductor storage device through the input/output pad and configured to control the semiconductor storage device, where each of the second circuit elements includes a first gate structure and a second gate structure on the substrate and spaced apart from each other in a first direction, individual source/drain regions on an external side of the first gate structure and the second gate structure in the first direction, and a common source/drain region between the first gate structure and the second gate structure, the common source/drain region includes a body portion aligned with the individual source/drain regions in the first direction and a protrusion protruding from one side of the body portion, between the first gate structure and the second gate structure, and each of the first gate structure and the second gate structure includes a gate protrusion protruding toward the protrusion in the first direction.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a plan view illustrating a semiconductor device according to example embodiments of the present disclosure;

FIG. 2A, 2B and 2C are cross-sectional views illustrating a semiconductor device according to example embodiments of the present disclosure;

FIGS. 3, 4, 5, 6 and 7 are plan views illustrating a semiconductor device according to example embodiments of the present disclosure;

FIG. 8 is a cross-sectional view illustrating a semiconductor device according to example embodiments of the present disclosure;

FIG. 9 is a plan view illustrating a portion of the semiconductor device illustrated in FIG. 8;

FIG. 10A is an enlarged cross-section view illustrating a portion of the semiconductor device illustrated in FIG. 8 according to example embodiments of the present disclosure; and

FIG. 10B is an enlarged cross-sectional view illustrating the semiconductor device illustrated in FIG. 9 according to example embodiments of the present disclosure;

FIG. 11 is a cross-sectional view illustrating a semiconductor device according to example embodiments of the present disclosure;

FIGS. 12A, 12B, 12C, 12D, 12E, and 12F are cross-sectional views illustrating a method of manufacturing a semiconductor device according to example embodiments of the present disclosure;

FIG. 13 is a diagram illustrating a data storage system including a semiconductor device according to example embodiments of the present disclosure; and

FIG. 14 is a perspective diagram illustrating a data storage system including a semiconductor device according to example embodiments of the present disclosure.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, "at least one of a, b, and c," should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

Terms such as first, second, etc. may be used to describe various components, but are used only for the purpose of distinguishing one component from another component. These terms do not limit the difference in the material or structure of the components.

The terms of a singular form may include plural forms unless otherwise specified. In addition, when a certain part “includes” a certain component, it means that other components may be further included rather than excluding other components unless otherwise stated. The use of the term “the” and similar designating terms may correspond to both the singular and the plural.

Operations of a method may be performed in an appropriate order unless explicitly described in terms of order. In addition, the use of all illustrative terms (e.g., etc.) is merely for describing technical ideas in detail, and the scope is not limited by these examples or illustrative terms unless limited by the claims.

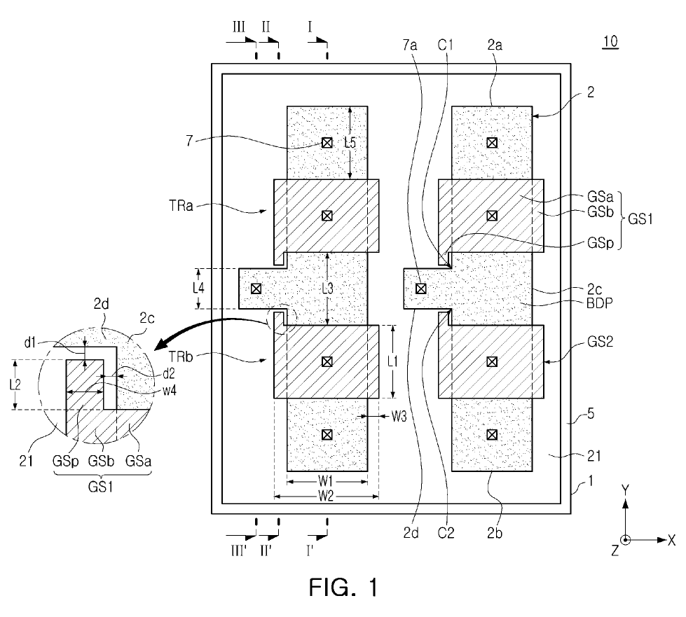

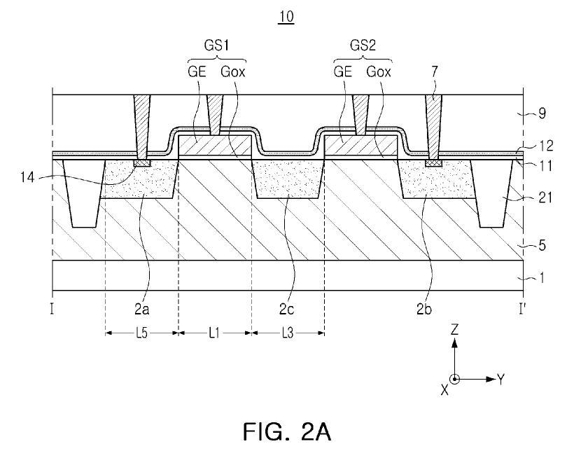

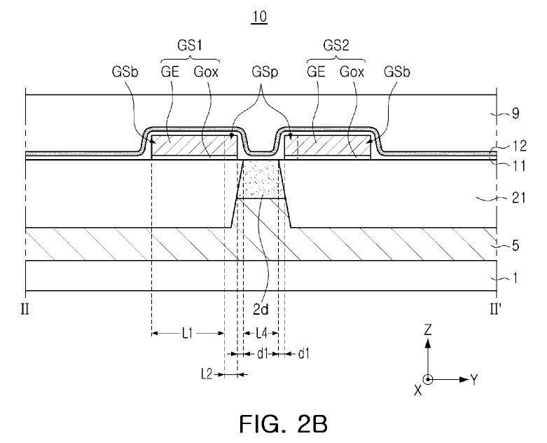

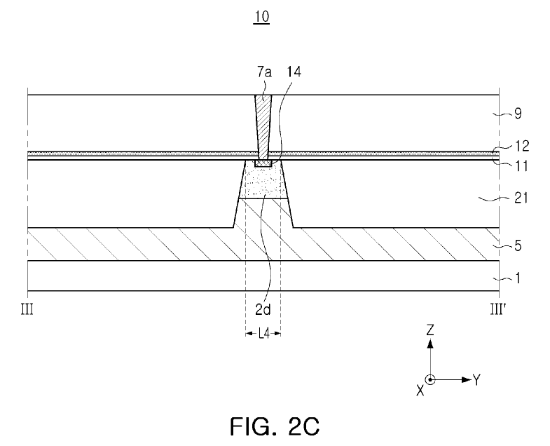

FIG. 1 is a plan view illustrating a semiconductor device according to example embodiments. FIGS. 2A, 2B, and 2C are cross-sectional views illustrating a semiconductor device according to example embodiments. FIG. 2A is a cross-sectional view illustrating the semiconductor device in FIG. 1 taken along line I-I’. FIG. 2B is a cross-sectional view illustrating the semiconductor device in FIG. 1 taken along line II-II’, and FIG. 2C is a cross-sectional view illustrating the semiconductor device in FIG. 1 taken along line III-III’.

The semiconductor device 10 may include circuit elements TRa and TRb. The semiconductor device 10 may include a substrate 1, device isolation layers 21 in the substrate 1, and circuit elements TRa and TRb as transistors disposed on the substrate 1.

The substrate 1 may have an upper surface extending in the X-direction and the Y-direction. The device isolation layers 21 may be formed on the substrate 1 and may define active regions 2. First and second source/drain regions 2a and 2b and a common source/drain region 2c, which include impurities, may be disposed in a portion of the active regions 2.

The substrate 1 may include a semiconductor material, such as a group IV semiconductor, a group III-V compound semiconductor, or a group II-VI compound semiconductor. For example, the substrate 1 may be provided as a single-crystal silicon bulk wafer.

Depending on the conductivity-type of the circuit elements TRa and TRb, a well region 5 may be disposed in the substrate 1. For example, when n-type metal-oxide-semiconductor (MOS) (NMOS) transistors are disposed as the circuit elements TRa and TRb, the well region 5 doped with P-type impurities may be disposed. However, embodiments are not limited thereto, and when the substrate 1 is configured as a P-type semiconductor, the circuit elements TRa and TRb, which are NMOS transistors, may be directly disposed in the substrate 1.

The device isolation layers 21 may define active regions 2 in the substrate 1. The device isolation layers 21 may be disposed in the well regions 5, respectively, and may be disposed to define the active regions 2 of each transistor. The device isolation layers 21 may be formed, for example, by a shallow trench isolation (STI) process. In example embodiments, a layout and a depth of the device isolation layers 21 may be varied. The device isolation layers 21 may be formed of an insulating material. The device isolation layer 21 may be, for example, an oxide, a nitride, or a combination thereof.

The circuit elements TRa and TRb may be disposed in a matrix in the well region 5. The circuit elements TRa and TRb may be disposed on the upper surface of the substrate 1 and may include planar transistors.

The circuit elements TRa and TRb may include at least two transistors TRa and TRb including a common source/drain region 2c in which at least two transistors TRa and TRb share a source/drain region. At least two transistors TRa and TRb may be connected to each other in series or in parallel depending on a circuit design.

The circuit elements TRa and TRb may include the active region 2 in which at least two transistors TRa and TRb are disposed. The active region 2 may be surrounded by the device isolation layers 21 and may be defined as a portion of the substrate 1.

The active region 2 may include a body region having a bar-type body portion BDP extending in the Y-direction as illustrated in FIG. 1, and a protrusion 2d protruding from a center of the body portion BDP and from one side of the body portion BDP in the X-direction.

The protrusion 2d may protrude and extend in a direction perpendicular to the extension direction (Y-direction) of the body portion BDP, and the protrusion 2d and the body portion BDP may be integrated and may form one active region 2.

When at least two transistors are disposed in the body portion BDP of the active region 2, the first source/drain region 2a, the first channel region, the common source/drain region 2c, the second channel region, and the second source/drain region 2b may be disposed in sequence in the Y-direction. The first and second channel regions may be defined as active regions 2 being overlapped by the first and second gate structures GS1 and GS2 in the Z-direction.

The first source/drain region 2a, the first channel region, the common source/drain region 2c, the second channel region, and the second source/drain region 2b disposed in sequence in the Y-direction in the body portion BDP may have the same first width W1 in the X-direction, and may have different lengths in the Y-direction, but embodiments are not limited thereto.

For example, the length L5 of the first source/drain region 2a and the second source/drain region 2b in the Y-direction may be the same, and the lengths of the first channel region and the second channel region may also be the same.

The common source/drain region 2c disposed in the center of the body region may have substantially the same length as that of the first source/drain region 2a, but embodiments are not limited thereto, and the common source/drain region 2c may have a length L3 in the Y-direction greater than the length of the first source/drain region 2a in the Y-direction depending on a design.

The protrusion 2d may protrude in the X-direction from a center of one side of the common source/drain region 2c and may have a length L4 less than the length L3 of the common source/drain region 2c in the Y-direction.

The protrusion 2d may be a contact region of the common source/drain region 2c and may contact the contact plug 7a.

The protrusion 2d may have a protruding length L3 in the Y-direction and may extend in the X-direction, and the extending width may be less than the first width W1.

Accordingly, the common source/drain region 2c may include a first portion that is the body portion BDP and a second portion that is the protrusion 2d. Accordingly, the protrusion 2d may be understood as a portion of the common source/drain region 2c, and the first portion and the second portion of the common source/drain region 2c may be physically and electrically integrated. The common source/drain region 2c may include a first bent portion C1 and a second bent portion C2 due to a difference in lengths in the Y-direction between the body portion BDP and the protrusion 2d. That is, the common source/drain region 2c may include corners C1 and C2 that are formed due to the extension of the protrusion 2d from the body portion BDP.

In the Y-direction, the first bent portion C1 may be a region bent upwardly from the protrusion 2d toward the first source/drain region 2a, and the second bent portion C2 may be a region bent downwardly from the protrusion 2d toward the second source/drain region 2b.

The first bent portion C1 and the second bent portion C2 may have substantially the same shape, but embodiments are not limited thereto, and the sizes of the first bent portion C1 and the second bent portion C2 may be different from each other depending on the arrangement of the circuit elements TRa and TRb.

The first and second source/drain regions 2a and 2b and the common source/drain region 2c may be regions doped with impurities of the same conductivity-type. For example, when the well region 5 is doped with P-type impurities, the first and second source/drain regions 2a and 2b and the common source/drain region 2c may be doped with N-type impurities, which may be different conductivity-types from that of the well region 5.

The concentrations of the impurities in the first and second source/drain regions 2a and 2b and the common source/drain region 2c may be the same.

The two transistors TRa and TRb of the circuit elements TRa and TRb may include gate structures GS1 and GS2 spaced apart from each other.

The first gate structure GS1 forming the first transistor TRa may include a gate dielectric layer Gox and a gate electrode GE.

The gate dielectric layer Gox may be disposed on an upper surface of the first channel region and may include an oxide or a nitride, preferably, silicon oxide (SiO₂).

The gate electrode GE is a metal base layer and may include a metal or a metal silicide. The gate electrode GE may include tungsten (W) or tungsten silicide (WSi₂), but embodiments are not limited thereto.

When the gate electrode GE includes tungsten silicide, the gate electrode GE may have resistance properties lower than that of polysilicon and high oxide compatibility, such that an additional electrode stack structure may not be necessary.

The first gate structure GS1 may further include a mask layer on the gate electrode GE, but embodiments are not limited thereto. The mask layer may include silicon nitride, silicon oxynitride, or the like.

The first gate structure GS1 may include a base portion GSa overlapping the body region of the active region 2 on the X-Y plane in the Z-direction, extended portions GSb protruding from both sides of the base portion GSa and overlapping the device isolation layer 21 around the active region 2 in the Z-direction, and a gate protrusion GSp protruding in the Y-direction toward the protrusion 2d from at least one extended portion GSb. The base portion GSa and the extended portions GSb may be defined as a base region. Accordingly, the gate protrusion GSp may be regarded as protruding from the base region.

The base portion GSa, the extended portions GSb, and the gate protrusion GSp may form each of the gate structures GS1 and GS2, and the base portion GSa, the extended portions GSb extending from both sides of the base portion GSa, and the gate protrusion GSp extending from one end of the extended portion GSb may be integrated.

Accordingly, the base portion GSa may have the same first width W1 as that of the active region 2, and the extended portions GSb having a third width W3 may be disposed on both sides of the base portion GSa, so that the first gate structure GS1 may have a second width W2 greater than the first width W1 in the X-direction.

The extended portions GSb disposed on both sides of the base portion GSa may have different third widths W3, but embodiments are not limited thereto.

The gate protrusion GSp extending from one end of the extended portion GSb disposed on the same side as the protrusion 2d and toward the protrusion 2d may have a fourth width W4 less than that of the extended portion GSb in the X-direction and may extend in the Y-direction. The gate protrusion GSp may have a quadrangular shape, and for example, when the protrusion 2d has a quadrangular shape, one side may be connected to and continued from one side of the extended portion GSb, one side may be connected to the extended portion GSb, and two sides may be disposed to have predetermined spacing distances d1 and d2 from the common source/drain region 2c. In other words, the gate protrusion GSp may extend from the extended portion GSb toward the protrusion 2d, with one side being integrate with the extended portion GSb, and the remaining three sides being spaced apart from the protrusion 2d, and with the side that is opposite to the side that is integral with the extended portion GSb being spaced apart from the protrusion 2d by a first distance d1, and among the sides that are opposite each other in the second direction, the side that is most adjacent to the body portion BDP is spaced apart from the body portion BDP by a second distance d2.

For example, the side opposing the protrusion 2d among the sides of the gate protrusion GSp may be disposed to have a first spacing distance d1 from the protrusion 2d, and the side opposing the body portion BDP among the sides of the gate protrusion GSp may be disposed to have a second spacing distance d2 from the first portion, which is the body portion BDP. That is, the gate protrusion GSp may be offset in the Z-direction from the protrusion 2d, may be disposed to have the first and second spacing distances d1 and d2 so as to not overlap the common source/drain region 2c in the Z-direction, and may overlap the device isolation layer 21 in the Z-direction.

It may be understood that the gate protrusion GSp may be disposed to have the first and second spacing distances d1 and d2 from the bent portions C1 and C2 of the common source/drain region 2c. The first and second spacing distances d1 and d2 may be substantially the same or similar lengths as the thickness of the gate dielectric layer Gox, and may be, for example, between 1 and 5 times the gate dielectric layer Gox.

As described above, a portion of the gate structure GS1 and GS2 may be disposed to correspond to the bent portion C1 and C2 between the protrusion 2d and the body portion BDP of the common source/drain region 2c, or may be disposed to be offset without overlapping the common source/drain region 2c in the Z-direction.

Accordingly, the common source/drain region 2c may be affected by changing the shape of the gate structure GS1 and GS2 while maintaining the common source/drain region 2c and the channel region without increasing the channel region in the active region 2.

For example, when a turn-on voltage is applied to the first gate structure GS1 among the gate structures GS1 and GS2, and a drain voltage is applied to the protrusion 2d of the common source/drain region 2c, and when the first transistor TRa is turned on, a turn-on current may flow to the first channel region while causing a bottleneck phenomenon in the first bent portion C1 of the common source/drain region 2c. The turn-on current may flow to the shortest distance from the contact plug 7a on the protrusion 2d, and the shortest distance to the first channel region may pass through the first bent portion C1, such that the current may be concentrated at the first bent portion C1. In this case, as in an example embodiment, when the gate protrusion GSp is disposed in the region corresponding to the common source/drain region 2c, an electric field may be formed by the high turn-on voltage of the first gate structure GS1, such that electrons may be collected in the first bent portion C1 close to the gate protrusion GSp, and resistance of the first bent portion C1 may relatively increases, and accordingly, the turn-on current may flow widely to the outside of the first bent portion C1. Accordingly, the turn-on current may flow evenly through the entire area of the common source/drain region 2c, such that the element defect due to a bottleneck phenomenon may be prevented.

Also, when the first transistor TRa is turned off, and when a relatively low voltage, for example, 0 V, is applied to the common source/drain region 2c, holes may be relatively collected in the first bent portion C1 close to the first gate structure GSa. In this case, the previously concentrated electrons and the newly collected holes may combine such that a depletion region may be formed in the first bent portion C1, which may indicate that a relatively high resistance value is configured in the first bent portion C1. Accordingly, when the turn-off voltage is applied, the off current may be blocked by the contact plug 7a on the common source/drain region 2c, such that the leakage current may be significantly reduced. Accordingly, the turn-on current may be increased when turned on, and the leakage current may be reduced when turned off, such that element reliability may be ensured.

The gate protrusion GSp may be disposed in the same manner in the second gate structure GS2.

The second gate structure GS2 may include a gate dielectric layer Gox and a gate electrode GE similarly to the first gate structure GS1, and may include a base portion GSa, two extended portions GSb and a gate protrusion GSp on the X-Y plane.

The size of the second gate structure GS2 may be substantially the same as that of the first gate structure GS1, but embodiments are not limited thereto. However, the two first and second gate structures GS1 and GS2 disposed on the active region 2 having first width W1 may have the same width W2, and accordingly, the gate protrusion GSp of the first gate structure GS1 may have the same shape as that of the gate protrusion GSp of the second gate structure GS2, and may be disposed symmetrically with respect to the protrusion 2d.

Accordingly, when the gate protrusion GSp of the first gate structure GS1 is disposed to correspond to the first bent portion C1, the gate protrusion GSp of the second gate structure GS2 may be disposed to correspond to the second bent portion C2.

The first and second spacing distances d1 and d2 between the gate protrusion GSp of the second gate structure GS2 and the second bent portion C2 may also be the same as the first and second spacing distances d1 and d2 of the gate protrusion GSp of the first gate structure GS1 and the first bent portion C1.

Accordingly, the spacing distances in the Y-direction between the first gate structure GS1 and the second gate structure GS2 may be the same as the third length L3 in the Y-direction of the body portion BDP of the common source/drain region 2c, and the gate protrusion GSp extending from one extended portion GSb of the second gate structure GS2 may be aligned with the gate protrusion GSp of the first gate structure GS1 in the Y-direction.

As described above, each of the gate structure GS1 and GS2 may have an angular shape, for example, a quadrangular shape, formed by the base portion GSa and the extended portions GSb, and may include the gate protrusion GSp protruding from one end of the quadrangular shape.

As the gate protrusions GSp are disposed symmetrically with respect to the protrusion 2d of the active region 2, the first and second transistors TRa and TRb may equally affect the common source/drain region 2c.

Accordingly, the circuit element including the common source/drain region 2c may include the first and second transistors TRa and TRb, and the first transistor TRa may include the first gate structure GS1, the first source/drain region 2a and the common source/drain region 2c on both sides of the first gate structure GS1, and the second transistor TRb may include the second gate structure GS2, the second source/drain region 2b and the common source/drain region 2c on both sides of the second gate structure GS2. Accordingly, the common source/drain region 2c may be shared by the two transistors TRa and TRb connected in series or in parallel.

A first substrate insulating layer 11 and a second substrate insulating layer 12 may be disposed by covering the circuit elements TRa and TRb.

The first substrate insulating layer 11 may be at least one of an oxide and an oxynitride, and may be, for example, a silicon oxide film. The first substrate insulating layer 11 may cover an upper surface of the substrate 1 and may be disposed conformally along the shape of the gate structures GS1 and GS2, but may be disposed to have a greater thickness on the side surfaces of the gate structures GS1 and GS2 due to a step difference between the substrate 1 and the gate structures GS1 and GS2. Accordingly, the side surfaces of the gate structures GS1 and GS2 may be protected by the first substrate insulating layer 11 without a gate spacer. However, the shape of the gate structures GS1 and GS2 is not limited thereto, and a gate spacer may be further included. However, even when the gate spacer is disposed, a thickness thereof may be less than the thickness of the gate dielectric layer Gox.

The second substrate insulating layer 12 may include a material different from that of the first substrate insulating layer 11, and may include a nitride, for example, silicon nitride. The second substrate insulating layer 12 may have a thickness less than that of the first substrate insulating layer 11 and may be conformally disposed on the first substrate insulating layer 11.

The upper insulating layer 9 may be disposed by covering the second substrate insulating layer 12. The upper insulating layer 9 may be formed of at least one of oxide, nitride, or oxynitride.

The contact plugs 7 may be disposed by penetrating the upper insulating layer 9, and the first and second substrate insulating layers 11 and 12.

The contact plugs 7 may be disposed in the first and second gate structures GS1 and GS2, respectively, and may be disposed in the first and second source/drain regions 2a and 2b, respectively. The contact plugs 7 may include a common contact plug 7a disposed in the common source/drain region 2c. The common contact plug 7a may contact the contact region 14 of the protrusion 2d protruding from the body portion BDP to allow a current to flow to the first and second channel regions disposed on both sides. Accordingly, the distance from the common contact plug 7a to the first and second channel regions on both sides may be ensured such that the current may flow uniformly, thereby ensuring element reliability.

The contact regions 14 of high concentration may be disposed in the first and second source/drain regions 2a and 2b and the common source/drain region 2c contacting the contact plugs 7. In this case, the contact regions 14 may include impurities of the same conductivity-type as that of the impurities of the common source/drain region 2c at a concentration greater than the concentration of the common source/drain region 2c.

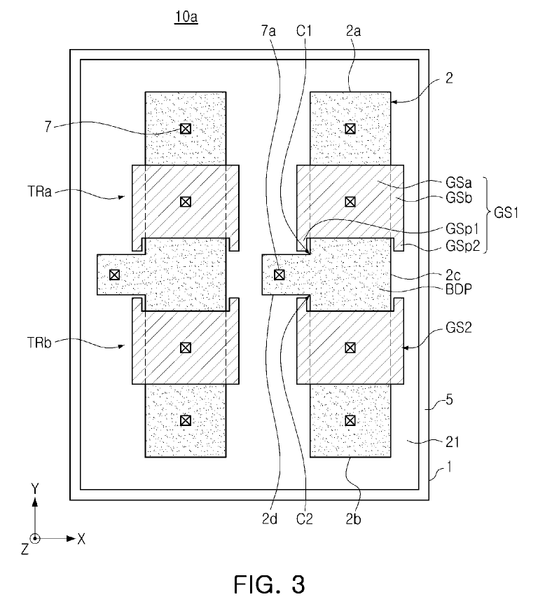

Hereinafter, a semiconductor device according to an example embodiment will be described with reference to FIGS. 3, 4, 5, 6 and 7.

FIGS. 3, 4, 5, 6 and 7 are plan views illustrating a semiconductor device according to example embodiments of the present disclosure.

The semiconductor device 10a in FIG. 3 may be the same as the semiconductor device 10 in FIGS. 1, 2A, 2B and 2C, other than the configuration in which the gate protrusions GSp1 and GSp2 of the gate structures GS1 and GS2 protrude from the extended portions GSb, respectively.

Specifically, in the semiconductor device 10a in FIG. 3, in each of the circuit elements TRa and TRb, the first gate structure GS1 and the second gate structure GS2 may be symmetrically disposed with respect to the common source/drain region 2c.

The first and second gate structures GS1 and GS2 may include the base portion GSa and extended portions GSb disposed on both sides of the base portion GSa and disposed on the device isolation layer 21, respectively.

The gate protrusion GSp1 and GSp2 may be disposed from the two extended portions GSb toward the common source/drain region 2c, respectively. The left-side gate protrusion GSp1 may have the same structure as in FIG. 1, and the right-side gate protrusion GSp2 may have the same shape as the left-side gate protrusion GSp1, and may be spaced apart from the common source/drain region 2c and may be disposed on the device isolation layer 21.

Accordingly, the first and second gate structures GS1 and GS2 may include the left-side gate protrusion GSp1 corresponding to the first and second bent portions C1 and C2, and the right-side gate protrusion GSp2 disposed on the opposite side of the left-side gate protrusion GSp1 and disposed on the device isolation layer 21 along the active region 2 in the region without the bent portion.

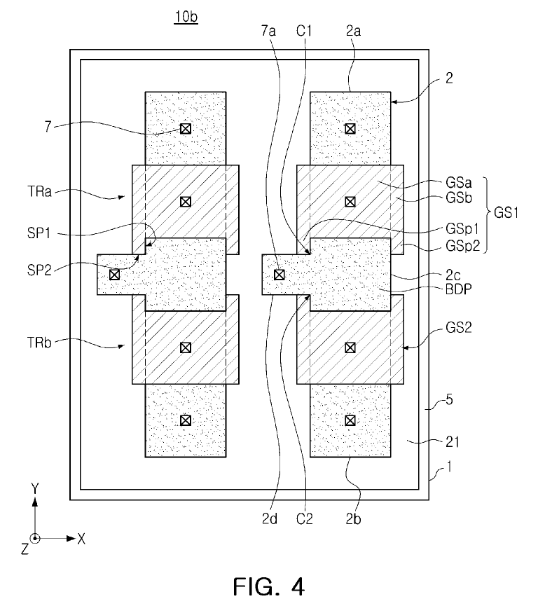

The semiconductor device 10b in FIG. 4 may be the same as the semiconductor device 10a in FIG. 3, other than the configuration in which the gate protrusions GSp of the first and second gate structures GS1 and GS2 are disposed to contact the common source/drain region 2c.

Specifically, the semiconductor device 10b in FIG. 4 may include the left-side gate protrusion GSp1 and the right-side gate protrusion GSp2 in the first gate structure GS1 and the second gate structure GS2 in the circuit elements TRa and TRb, respectively.

In this case, the left-side gate protrusion GSp1 may be disposed to not have a spacing distance from the first and second bent portions C1 and C2 (e.g., d1 and d2 shown in FIG. 1 are substantially zero in the semiconductor device 10b). The left-side gate protrusion GSp1 may be disposed on the device isolation layer 21 and may not overlap the common source/drain region 2c in the Z-direction. In this case, the left-side gate protrusion GSp1 may be disposed such that the side surface thereof may contact the first and second bent portions C1 and C2. Accordingly, one side surface SP1 of the left-side gate protrusion GSp1 may be aligned with one side surface of the body portion BDP in the Z-direction, and the other side surface SP2 of the left-side gate protrusion GSp1 may be aligned with one side surface of the protrusion 2d in the Z-direction. Accordingly, apexes of the left-side gate protrusion GSp1 may coincide with bend points (e.g., corners) of the first and second bent portions C1 and C2. That is, the left-side gate protrusion GSp1 may not overlap the common source/drain region 2c, but may be disposed relatively close to the common source/drain region 2c.

The right-side gate protrusion GSp2 may also be disposed such that the side surface thereof may be close to a side surface of the body portion BDP in the Z-direction to be aligned with the side surface.

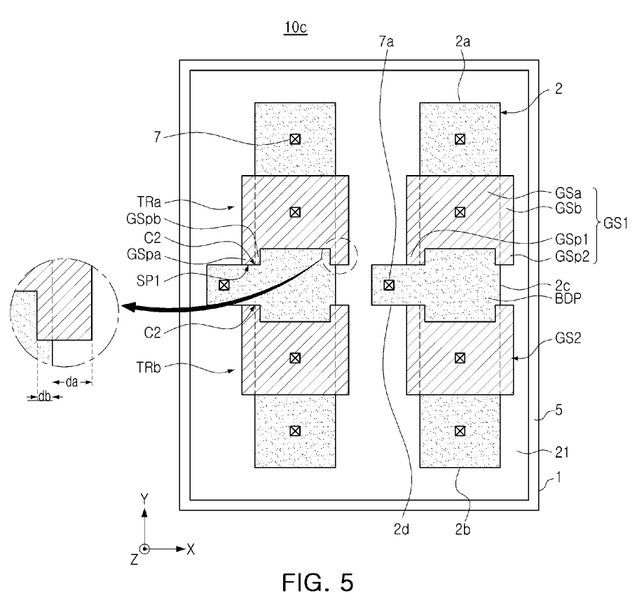

The semiconductor device 10c in FIG. 5 may be the same as the semiconductor device 10a in FIG. 3, other than the configuration in which the gate protrusion GSp of the gate structure partially overlap with the common source/drain region 2c.

Specifically, the semiconductor device 10c in FIG. 5 may include the left-side gate protrusion GSp1 and the right-side gate protrusion GSp2 in the first gate structure GS1 and the second gate structure GS2 in the circuit elements TRa and TRb, respectively.

In this case, the left-side gate protrusion GSp1 may be disposed to not have a spacing distance from the first and second bent portions C1 and C2 (d1 and d2 shown in FIG. 1 are substantially zero in the semiconductor device 10c). The left-side gate protrusion GSp1 may include a first protrusion region GSpa disposed on the device isolation layer 21 and not overlapping the common source/drain region 2c in the Z direction, and a second protrusion region GSpb disposed consecutively with the first protrusion region GSpa and overlapping the common source/drain region 2c in the Z-direction. In this case, the side surface SP1 of the left-side gate protrusion GSp1 may be aligned with one side surface of the protrusion 2d in the Z-direction. That is, as the left-side gate protrusion GSp1 extends toward the body portion BDP side, the channel region in a portion of the first and second bent portions C1 and C2 may have a bent shape along the second protrusion region GSpb, but impurities may be diffused into a lower portion of the second protrusion region GSpb at low concentration, thereby actually functioning as the common source/drain region 2c.

However, the left-side gate protrusion GSp1 may not extend to overlap the protrusion 2d in the Z-direction, such that the current flowing from the protrusion 2d may be prevented from being suddenly bottlenecked at the bent portion C1 and C2.

The right-side gate protrusion GSp2 may also extend to partially overlap the body portion BDP.

In this case, the length da of the first protrusion region GSpa in the X-direction and the length db of the second protrusion region GSpb in the X-direction may be substantially the same, but the length db of the second protrusion region GSpb may be less than the length da of the first protrusion region GSpa.

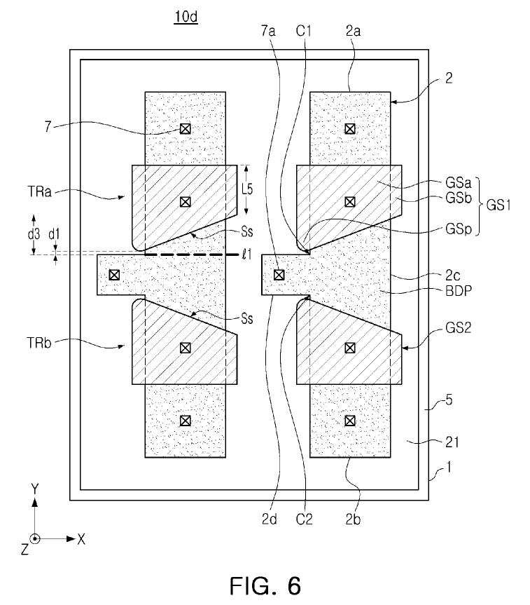

The semiconductor device 10d in FIG. 6 may be the same as the semiconductor device 10a in FIG. 3 other than the shapes of the gate structures GS1 and GS2.

Specifically, in the semiconductor device 10d in FIG. 6, in each of the circuit elements TRa and TRb, the first gate structure GS1 and the second gate structure GS2 may be disposed symmetrically around the common source/drain region 2c, and the shapes thereof may also be disposed symmetrically to each other.

Each of the first and second gate structures GS1 and GS2 may include a base portion GSa and extended portions GSb disposed on both sides of the base portion GSa above the device isolation layer 21. The first side surface Ss of the first and second gate structures GS1 and GS2 may have a slope directed to the common source/drain region 2c. Specifically, the first side surface Ss may be disposed such that the distance in the Y-direction from the extended line l1 of the side surface of the protrusion 2d from one end approaching protrusion 2d to the other end may increase. That is, the lengths in the Y-direction of the first and second gate structures GS1 and GS2 may be less in a direction away from the protrusion 2d, and the change in length may be determined by the slope of the first side surface Ss. That is, in a corresponding gate structure, such as gate structure GS1, in the Y-direction, the length of the side of the gate structure GS1 that is nearest to the protrusion 2d in the X-direction is greater than the length of the side of the gate structure GS1 that is farthest from the protrusion 2d in the X-direction.

The second gate structure GS2 also may include a first side surface Ss, and the first gate structure GS1 and the second gate structure GS2 may have a symmetrical structure with respect to the extended line l1 in the X-direction of the side surface of the protrusion 2d, the elements are disposed close to the first and second gate structures GS1 and GS2 in the region close to the protrusion 2d. The shortest distance may satisfy the first spacing distance d1, and the spacing distance may increase in the region far from the protrusion 2d, but the maximum spacing distance d3 may be less than the length L5 of the short side surface of the first and second gate structures GS1 and GS2. Accordingly, the channel region of the transistors TRa and TRb may be shortened on the side without the protrusion 2d. Accordingly, the bent portion C1 and C2 may be affected by the electric field of the gate structures GS1 and GS2 to prevent a bottleneck phenomenon of current.

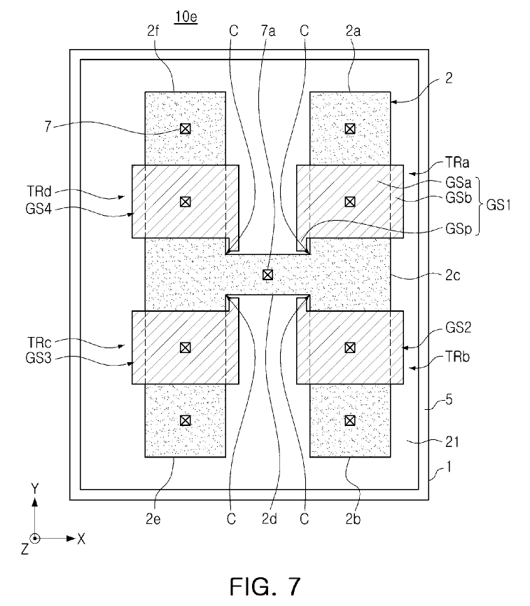

The semiconductor device 10e in FIG. 7 may be the same as the semiconductor device 10 in FIGS. 1, 2A, 2B and 2C other than the configuration in which circuit elements TRa, TRb, TRc, and TRd include four transistors TRa, TRb, TRc, and TRd, respectively.

Specifically, the semiconductor device 10e in FIG. 7 may include an H-shaped active region 2 in each of the circuit elements TRa, TRb, TRc, and TRd, a common source/drain region 2c may be disposed in the central region of the active region 2, and first to fourth source/drain regions 2a, 2b, 2e, and 2f may be disposed on both ends, respectively.

First to fourth channel regions may be disposed between the first to fourth source/drain regions 2a, 2b, 2e, and 2f and the common source/drain region 2c, and first to fourth gate structures GS1, GS2, GS3, and GS4 may be disposed by covering the first to fourth channel regions, respectively.

The center of the common source/drain region 2c, that is, the bar region which is the center of the H-shaped active region 2, may be a region in which the common contact plug 7c is disposed as the protrusion 2d, and it may be understood that the individual first to fourth source/drain regions 2a, 2b, 2e, and 2f and the first to fourth gate structures GS1, GS2, GS3, and GS4 may be disposed in the four bar regions bent with protrusion 2d.

Accordingly, the first to fourth transistors TRa, TRb, TRc, and TRd may include the first to fourth gate structures GS1, GS2, GS3, and GS4, the first to fourth source/drain regions 2a, 2b, 2e, and 2f on one sides of the gate structure GS1, GS2, GS3, and GS4, respectively, and the common source/drain region 2c.

Each of the gate structure GS1, GS2, GS3, and GS4 may include gate protrusions GSp to correspond to the bent portions C of the H-shaped active region 2.

The shape of the gate protrusions GSp and the shape of the gate structure may be the same as in FIGS. 1, 2A, 2B and 2C. Accordingly, an electric field may be applied such that the gate protrusions GSp may allow a current to uniformly flow from the protrusion 2d.

Various circuit elements illustrated in FIGS. 1, 2A, 2B, 2C, 3, 4, 5, 6, and 7 are applicable to circuit designs of various semiconductor devices.

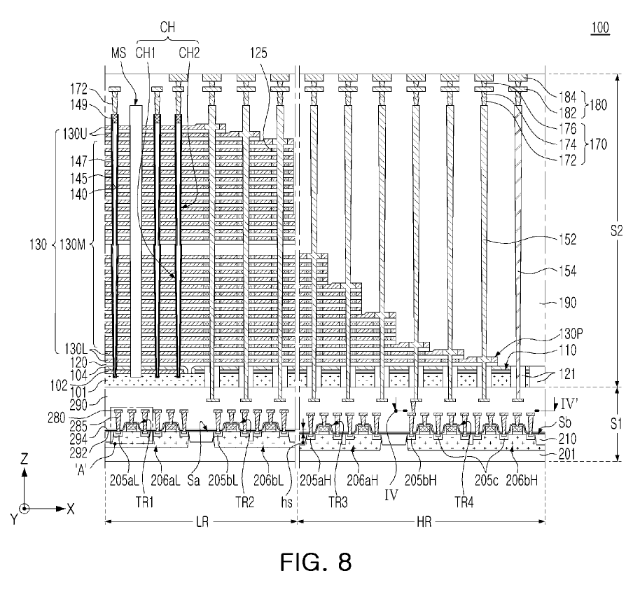

Hereinafter, an example in which the semiconductor device 10 in FIGS. 1, 2A, 2B, 2C, 3, 4, 5, 6, and 7 is applied to a portion of a peripheral circuit structure of a memory device will be described with reference to FIGS. 8, 9, 10A, and 10B.

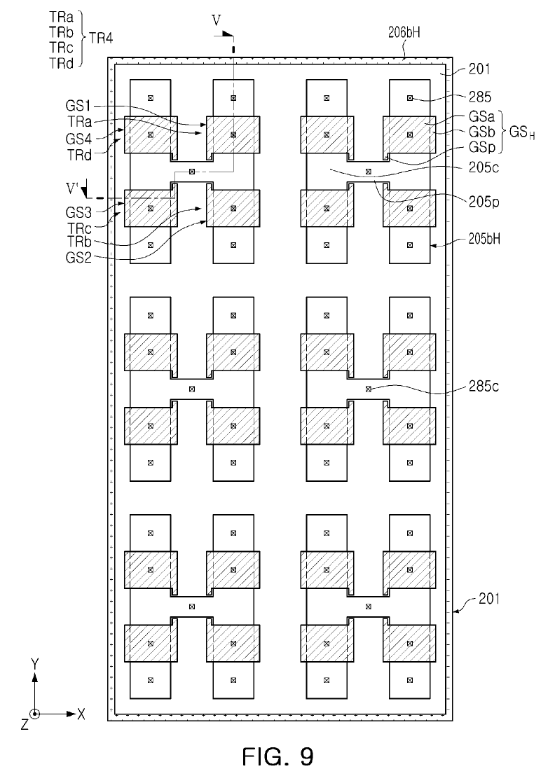

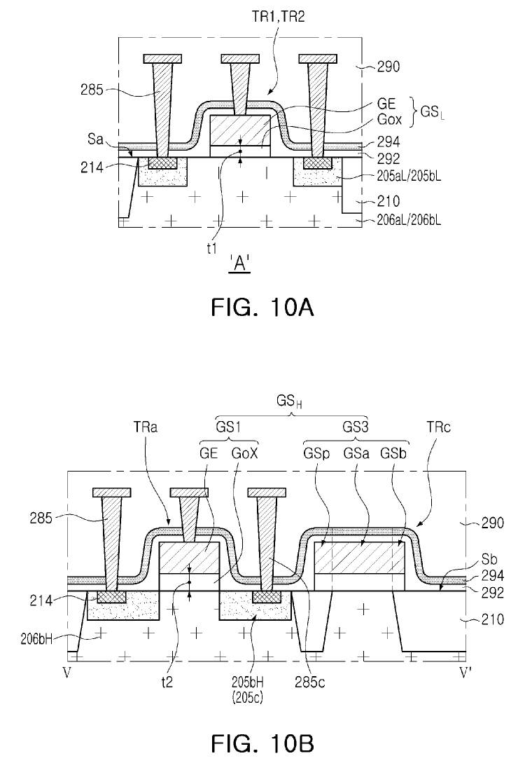

FIGS. 8, 9, 10A, and 10B illustrate a semiconductor device according to an example embodiment. FIG. 8 is a cross-sectional diagram illustrating a semiconductor device according to an example embodiment, FIG. 9 is a plan diagram illustrating circuit elements in FIG. 8 taken along line IV-IV’, FIG. 10A is an enlarged diagram illustrating region A in FIG. 8, and FIG. 10B is a cross-sectional diagram illustrating the example in FIG. 9 taken along line V-V’.

Referring to FIGS. 8, 9, 10A, and 10B, a semiconductor device 100 may include a first substrate structure S1 and a second substrate structure S2 disposed above the first substrate structure S1. The first substrate structure S1 may include a peripheral circuit structure, and the second substrate structure S2 may include a memory cell structure.

The first substrate structure S1 may have a low-voltage element region LR and a high-voltage element region HR. The low-voltage element region LR may be defined as a region in which circuit elements controllable with a relatively low drive voltage are disposed, and the high-voltage element region HR may be defined as a region in which circuit elements controllable with a relatively high drive voltage are disposed.

The first substrate structure S1 may include a substrate 201, device isolation layers 210 in the substrate 201, first circuit elements TR1 and second circuit elements TR2 disposed on the substrate 201 in the low-voltage element region LR, third circuit elements TR3 and fourth circuit elements TR4 disposed on the substrate 201 in the high-voltage element region HR, a peripheral region insulating layer 290 on an upper surface of the substrate 201, contact plugs 285 on the substrate 201, and circuit interconnection lines 280.

The first substrate structure S1 may include first and second well regions 206aL and 206bL and first and second source/drain regions 205aL and 205bL disposed in the low-voltage element region LR, and third and fourth well regions 206aH and 206bH and third and fourth source/drain regions 205aH and 205bH disposed in the high-voltage element region HR.

The substrate 201 may have an upper surface extending in the X-direction and the Y-direction.

The substrate 201 may include a first upper surface Sa disposed in the low-voltage element region LR and a second upper surface Sb disposed in the high-voltage element region HR, and the second upper surface Sb may be disposed at a lower level by the substrate step difference hs in the Z-direction from the first upper surface Sa. Accordingly, a starting point of the gate structure GS_{H} in the high-voltage element region HR may be disposed at lower level.

The substrate 201 may include a semiconductor material, for example, a group IV semiconductor, a group III-V compound semiconductor, or a group II-VI compound semiconductor. For example, the substrate 201 may be provided as a single-crystal silicon bulk wafer.

Complementary MOS (CMOS) transistors may be disposed in each of the low-voltage element region LR and the high-voltage element region HR, and the first and second well region 206aL/206bL and the third and fourth well region 206aH/206bH may be disposed in the substrate 201 such that transistors having different conductivity-types may be disposed in each element region LR/HR. When the substrate 201 is a P-type semiconductor, the first and third well region 206aL/206aH may be an N-type well doped with N-type impurities, and the second and fourth well region 206bL/206bH may be a P-type well doped with P-type impurities. When the conductivity type of the substrate 201 is opposite, the conductivity types of the well region may be opposite.

Device isolation layers 210 may be formed in the low-voltage element region LR and the high-voltage element region HR, respectively, and active regions may be defined. The device isolation layers 210 may be formed, for example, by a shallow trench isolation (STI) process. In example embodiments, the arrangement and depth of the device isolation layers 210 may be varied. The device isolation layers 210 may be formed of an insulating material. The device isolation layer 210 may be, for example, an oxide, a nitride, or a combination thereof.

First and second source/drain regions 205aL and 205bL, and third and fourth source/drain regions 205aH and 205bH including impurities and a common source/drain region 205c may be disposed in a portion of the active regions.

The low-voltage element region LR may include each of the first well region 206aL and the second well region 206bL, and when the substrate 201 includes P-type impurities, circuit elements may be formed directly on the substrate 201 without the P-type well region 206bL.

The high-voltage element region HR may include each of the third well region 206aH and the fourth well region 206bH, and when the substrate 201 includes P-type impurities, circuit elements may be formed directly on the substrate 201 without the P-type well region 206bH. Also, in addition to the P-type well region 206bH, a non-well region in which circuit elements are formed on the substrate 201 may also be included.

Accordingly, the first and second source/drain regions 205aL and 205bL in the low-voltage element region LR may be disposed in the first well region 206aL and the second well region 206bL, respectively, and may be doped with impurities of different conductivity types, and the third and fourth source/drain regions 205aH and 205bH in the high-voltage element region HR may be disposed in the third well region 206aH and the fourth well region 206bH, respectively, and may be doped with impurities of different conductivity types.

The first and third source/drain regions 205aL and 205aH in the first and third well region 206aL and 206aH in the low-voltage element region LR and the high-voltage element region HR may be doped with the same impurities, and the second and fourth source/drain regions 205bL and 205bH in the second and fourth well region 206bL and 206bH in the low-voltage element region LR and high-voltage element region HR may be doped with the same impurities.

The fourth well region 206bH in the high-voltage element region HR in the first substrate structure S1 of the semiconductor device 100 may correspond to the well region 5 of the semiconductor device described above with reference to FIGS. 1, 2A, 2B, 2C, 3, 4, 5, 6, and 7.

Accordingly, the circuit elements TRa and TRb, which are NMOS transistors in FIGS. 1, 2A, 2B, and 2C, may be the fourth circuit element TR4 of the high-voltage element region HR1.

The first circuit elements TR1 and the second circuit elements TR2 may be disposed in the low-voltage element region LR of the semiconductor device 100.

The first circuit elements TR1 may function as p-type MOS (PMOS) transistors on the first upper surface Sa of the substrate of the low-voltage element region LR, and the second circuit elements TR2 may function as NMOS transistors on the first upper surface Sa of the substrate of the low-voltage element region LR.

In FIGS. 8 and 10A, the sizes, for example, the channel length, of the circuit elements TR1 and TR2 of the low-voltage element region LR are illustrated as being the same as or similar to each other, but embodiments are not limited thereto, and the sizes may be different from each other.

The first circuit elements TR1 and the second circuit elements TR2 may be disposed in the well regions 206aL and 206bL having each conductivity-type. In FIG. 8, the substrate 201 may be a P-type substrate 201, and the first circuit elements TR1 may be disposed in the first well region 206aL doped with N-type impurities, and the second circuit elements TR2 may be disposed in the second well region 206bL doped with P-type impurities.

The first circuit elements TR1 and the second circuit elements TR2 may be planar transistors, and may include a gate structure GS_{L} and first or second source/drain regions 205aL and 205bL on the first upper surface Sa of the substrate 201.

The gate structure GS_{L} may include a gate dielectric layer Gox and a gate electrode GE.

The gate dielectric layer Gox may include a high-κ material, and for example, hafnium oxide. The gate dielectric layer Gox may have a first thickness t1, and the first thickness t1 may have a thickness less than the gate dielectric layer Gox of the high-voltage element region HR.

The gate electrode GE may include a metal silicide, similarly to the gate electrode GE in FIGS. 1, 2A, 2B, and 2C, and may include, for example, tungsten silicide. Accordingly, a conductive layer may be formed to have a low resistance with a low thickness.

Alternatively, the gate electrode GE may include a metal such as polysilicon, tungsten, or aluminum, and when including a metal, an ohmic contact layer may be further included. A mask layer may be further included on an upper portion of the gate electrode GE. The mask layer may include silicon nitride, silicon oxynitride, or the like.

When the second circuit element TR2 is configured as an NMOS transistor, differently from the first circuit element TR1, a channel structure may be further included between the substrate and the gate dielectric layer Gox. The channel structure may include a semiconductor material having a band gap smaller than that of the substrate 201 on the first upper surface Sa of the substrate 201. For example, when the substrate 201 includes silicon, the channel structure may include silicon-germanium (SiGe).

Each of the first and second circuit elements TR1 and TR2 may form a transistor, but embodiments are not limited thereto. The first and second circuit elements TR1 and TR2 may include first and second source/drain regions 205aL and 205bL on both sides of the gate structure GS_{L}, respectively.

A device isolation layer 210 cutting the first source/drain region 205aL may be disposed between neighboring first circuit elements TR1, but embodiments are not limited thereto. A shared source/drain region may be included depending on a circuit design.

The first and second source/drain regions 205aL and 205bL may include a contact region 214 in a region contacting the contact plug 285, and the contact region 214 may be doped with a high concentration of impurities.

A first substrate insulating layer 292 and a second substrate insulating layer 294 may be disposed by covering the first and second circuit elements TR1 and TR2.

The first substrate insulating layer 292 may be at least one of an oxide and an oxynitride, for example, a silicon oxide film. The first substrate insulating layer 292 covers an upper surface of the substrate 201 and may be disposed conformally along the shape of the gate structures 205aL and 205bL, and may be disposed to have a greater thickness on the side surface of the gate structure GS_{L} due to the step difference between the substrate and the gate structure GS_{L}. Accordingly, the side surface of the gate structure GS_{L} may be protected by the first substrate insulating layer 292 without a gate spacer. However, the shape of the gate structure GS_{L} is not limited thereto, and a gate spacer may be further included. However, even when the gate spacer is disposed, the gate spacer may be disposed with a thickness less than that of the gate dielectric layer Gox.

The second substrate insulating layer 294 may include a material different from that of the first substrate insulating layer 292, and may include nitride, and may include silicon nitride, for example. The second substrate insulating layer 294 may have a thickness less than that of the first substrate insulating layer 292, and may be conformally disposed on the first substrate insulating layer 292.

The peripheral region insulating layer 290 may be disposed by covering the second substrate insulating layer 294. The peripheral region insulating layer 290 may be formed of at least one of oxide, nitride, or oxynitride.

The contact plugs 285 may be disposed by penetrating the peripheral region insulating layer 290, and the first and second substrate insulating layers 292 and 294.

The contact plugs 285 may be disposed in each of the gate structure GS_{L}, and may be disposed in each of the first and second source/drain regions 205aL and 205bL.

Third circuit elements TR3 and fourth circuit elements TR4 may be further disposed in the high-voltage element region HR of the semiconductor device 100.

The third circuit elements TR3 may function as PMOS transistors on the second upper surface Sb of the high-voltage element region HR, and the fourth circuit elements TR4 may function as NMOS transistors on the second upper surface Sb of the high-voltage element region HR.

In FIGS. 8, 9, and 10B, the sizes of the circuit elements TR3 and TR4 of the high-voltage element region HR, for example, the channel length, or the like, are illustrated as being the same as or similar to those of the circuit elements TR1 and TR2 of the low-voltage element region LR, but embodiments are not limited thereto, and the sizes of the circuit elements TR3 and TR4 of the high-voltage element region HR, for example, the channel length, or the like, may be greater than those of the circuit elements TR1 and TR2.

The third circuit elements TR3 and the fourth circuit elements TR4 may be disposed in conductivity-type regions, respectively, and at least one of the elements may be disposed in the well regions 206aH and 206bH. In FIG. 8, the substrate 201 may be configured as a P-type substrate 201, and the third circuit elements TR3 may be disposed in the third well region 206aH doped with N-type impurities, and the fourth circuit elements TR4 may be disposed in the fourth well region 206bH doped with P-type impurities. However, embodiments are not limited thereto.

The third circuit elements TR3 and the fourth circuit elements TR4 may have the same gate structure GS_{H} and the stack structure other than the configuration in which the regions in which the third circuit elements TR3 and the fourth circuit elements TR4 are disposed are of different conductivity-types.

That is, the third circuit elements TR3 and the fourth circuit elements TR4 may be planar transistors and may include gate structure GS_{H}, and third and fourth source/drain regions 205aH and 205bH on the second upper surface Sb, which is at a level lower than a level of the first upper surface Sa of the substrate 201 by the substrate step difference hs. The gate structure GS_{H} may have a height greater than that of the gate structure GS_{L} of the first and second circuit elements TR1, TR2, but embodiments are not limited thereto.

The gate structure GS_{H} may include a gate dielectric layer Gox and a gate electrode GE.

The gate dielectric layer Gox may include a low-k material, and may include a material such as an oxide or nitride, preferably a silicon oxide film (SiO₂). The gate dielectric layer Gox may have a thickness t2 greater than the thickness t1 of the gate dielectric layer Gox of the first circuit element TR1 and the second circuit element TR2, and may have the thickness t2 substantially the same as the substrate step difference hs, but embodiments are not limited thereto.

The gate electrode GE may be disposed on the gate dielectric layer Gox, and may include the same material as that of the gate electrode GE in FIGS. 2A, 2B, and 2C. The gate electrode GE may include tungsten silicide, but embodiments are not limited thereto.

The gate electrode GE may include polysilicon, or a metal such as tungsten or aluminum, and may include substantially the same material as that of the gate electrode GE of the second circuit element TR2 and may have the same thickness as that of the gate electrode GE of the second circuit element TR2. A mask layer may be further included in an upper portion of the gate electrode GE. The mask layer may include silicon nitride, silicon oxynitride, or the like.

The third and fourth source/drain regions 205aH and 205bH may include impurities in the substrate 201 on both sides of the gate structure GS_{H}.

Specifically, the third source/drain regions 205aH may be disposed on both sides of the gate structure GS_{H}, and the third source/drain regions 205aH of the neighboring third circuit elements TR3 may be isolated by the device isolation layer 210.

The fourth circuit element TR4 including the fourth source drain regions 205bH may be configured such that four transistors TRa, TRb, TRc, and TRd may share one common source/drain region 205c as illustrated in FIG. 9.

Specifically, as in the semiconductor device in FIG. 7, each of the fourth circuit elements TRa, TRb, TRc, and TRd may include an H-shaped active region, and the common source/drain region 205c may be disposed in the central region of the active region, and the fourth source/drain regions 205bH may be disposed individually on four ends regions of the active region.

The channel regions of the transistors TRa, TRb, TRc, and TRd may be disposed between the fourth source/drain regions 205bH and the common source/drain region 205c, and the gate structures GS_{H} (GS1, GS2, GS3, and GS4) may be disposed by covering the channel regions, respectively.

The center of the common source/drain region 205c, that is, a bar region which is the center of the H-shaped active region, may be a region in which the common contact plug 285c is disposed as the protrusion 205p, and it may be understood that the individual fourth source/drain regions 205bH and the gate structures GS1, GS2, GS3, and GS4 may be disposed in the four bar regions bent with the protrusion 205p.

Accordingly, the four transistors TRa, TRb, TRc, and TRd may include gate structures GS1, GS2, GS3, and GS4, and fourth source/drain regions 205bH on one side of each of the gate structures GS1, GS2, GS3, and GS4 and a common source/drain region 205c on the other side.

The shape of the protrusion 205p, and the shape of each of the gate structures GS1, GS2, GS3, and GS4 may be the same as those in FIGS. 1, 2A, 2B, 2C and 7. Specifically, the gate structures GS1, GS2, GS3, and GS4 of the transistors TRa, TRb, TRc, and TRd of the fourth circuit elements TR4 may include a base portion GSa covering a channel region, an extended portion GSb extending from the base portion GSa to both sides, and a gate protrusion GSp protruding from one end of the extended portion GSb toward a bent portion.

Four gate protrusion GSp may be symmetrically disposed to correspond to four bent portions of the H-shaped active region, thereby increasing an on current of each of the transistors TRa, TRb, TRc, and TRd.

Accordingly, an electric field may be applied such that the gate protrusion GSp may allow current to uniformly flow from the protrusion 205c. Accordingly, when two or more transistors function as a pass circuit configured to transfer each voltage by a turn-on voltage which is a high-voltage, each of the fourth circuit elements TRa, TRb, TRc, and TRd may include a common source/drain region 205p such that integration density of the device and also the turn-on current may be ensured, thereby ensuring element reliability.

First and second substrate insulating layers 292 and 294 may be disposed in order by covering the third and fourth circuit elements TR3 and TR4.

The peripheral region insulating layer 290 may be disposed on the first to fourth circuit elements TR1-TR4 on the first and second upper surfaces Sa and Sb of the substrate 201. The peripheral region insulating layer 290 may include a plurality of insulating layers formed in different processes. The peripheral region insulating layer 290 may be formed of an insulating material, and may include, for example, at least one of oxide, nitride, or oxynitride.

The contact plugs 285 may penetrate the peripheral region insulating layer 290 and may be connected to the first to fourth source/drain regions 205aL 205bL, 205aH, and 205bH. A portion of the contact plugs 285 may penetrate the peripheral region insulating layer 290 and may be connected to the gate structures.

Each of the contact plugs 285 may have an inclined side surface such that a width of an upper surface may be greater than a width of a lower surface. Upper ends of the contact plugs 285 may be positioned substantially at the same level, but embodiments are not limited thereto.

Each of the contact plugs 285 may have a cylindrical shape. The contact plugs 285 may include a conductive material, for example, a semiconductor material, a metal-semiconductor compound, or at least one of metal materials such as tungsten (W), cobalt (Co), molybdenum (Mo), copper (Cu), ruthenium (Ru), or aluminum (Al), and each of the contact plugs 285 may further include a diffusion barrier. The contact plugs 285 and the circuit interconnection lines 280 may be disposed on an upper surface Sa and Sb of the substrate 201 and may be connected to each other.

Backside interconnection structures and a backside insulating layer may be further disposed on the backside of the substrate 201, and at least a portion of the backside interconnection structures may form a backside power delivery network (BSPDN), but embodiments are not limited thereto.

The second substrate structure S2 may include a plate layer 101, gate electrodes 130 stacked on an upper surface of the plate layer 101, interlayer insulating layers 120 alternately stacked with the gate electrodes 130, channel structures CH penetrating the gate electrodes 130, isolation regions MS penetrating the gate electrodes 130 and extending in one direction by, first cell contact plugs 152 connected to the gate electrodes 130, and second cell contact plugs 154 electrically connected to the plate layer 101. The second substrate structure S2 may further include a cover insulating layer 105, a passivation layer 106, contact insulating layers 125, cell upper contacts 170, cell interconnection lines 180, and cell region insulating layers 190.

The second substrate structure S2 may further include first and second horizontal conductive layers 102 and 104, a horizontal insulating structure 110, and a substrate through-insulating layer 121 on the plate layer 101.

The first and second horizontal conductive layers 102 and 104 may be stacked in order on an upper surface of the plate layer 101. The first horizontal conductive layer 102 may function as a portion of a common source line of the semiconductor device 100, for example, functioning as a common source line together with the plate layer 101. The first horizontal conductive layer 102 may be directly connected to the channel layer 140 around each of the channel layers 140 of the channel structures CH. The first and second horizontal conductive layers 102 and 104 may include a semiconductor material, for example, polycrystalline silicon.

The horizontal insulating structure 110 may be disposed on the plate layer 101 in parallel with the first horizontal conductive layer 102. The horizontal insulating structure 110 may include three horizontal insulating layers stacked in order on the plate layer 101. The horizontal insulating structure 110 may be layers remaining after a portion is replaced with the first horizontal conductive layer 102 in the process of manufacturing the semiconductor device 100a. The horizontal insulating structure 110 may include silicon oxide, silicon nitride, silicon carbide, or silicon oxynitride.

The substrate through-insulating layer 121 may be disposed to penetrate the plate layer 101, the horizontal insulating structure 110, and the second horizontal conductive layer 104. An upper surface of the substrate through-insulating layer 121 may be coplanar with an upper surface of the second horizontal conductive layer 104, but embodiments are not limited thereto. The substrate through-insulating layer 121 may include an insulating material, for example, silicon oxide, silicon nitride, silicon carbide, or silicon oxynitride.

In the example embodiment, the first and second cell contact plugs 152 and 154 may penetrate the gate electrodes 130, may penetrate the through-insulating layer 121 of the substrate 1 and may be connected to circuit interconnection lines 280 of the peripheral circuit region PERI.

The plate layer 101 may have an upper surface extending in the X-direction and the Y-direction. The plate layer 101 may function as a common source line of the semiconductor device 100. The plate layer 101 may include a conductive material. For example, the plate layer 101 may include a semiconductor material, such as a group IV semiconductor, a group III-V compound semiconductor, or a group II-VI compound semiconductor. For example, the group IV semiconductor may include silicon, germanium, or silicon-germanium. The plate layer 101 may further include impurities. The plate layer 101 may be provided as a polycrystalline semiconductor layer, such as a polycrystalline silicon layer, or an epitaxial layer. In example embodiments, the plate layer 101 may include a plurality of conductive layers vertically stacked.

The gate electrodes 130 may be vertically stacked and spaced apart from each other on an upper surface of the plate layer 101 and may form a stack structure with the interlayer insulating layers 120. The stack structure may include lower and upper stack structures vertically stacked and surrounding first and second channel structures CH1 and CH2, respectively. However, in example embodiments, the stack structure may be configured as an integrated stack structure.

The gate electrodes 130 may include at least one lower gate electrode 130L forming a gate of a ground select transistor, memory gate electrodes 130M forming a plurality of memory cells, and upper gate electrodes 130U forming gates of string select transistors. Here, the lower and upper stack structures, the lower gate electrode 130L, and the upper gate electrodes 130U may be referred to using the terms “lower” and “upper” based on the direction during the manufacturing process. The number of the memory gate electrodes 130M forming the memory cells may be determined depending on capacity of the semiconductor device 100. In an example embodiment, the number of each of the upper and lower gate electrodes 130U and 130L may be 1 to 4 or more, and may have a structure the same as or different from the structure of the memory gate electrodes 130M. In example embodiments, the gate electrodes 130 may further include a gate electrode 130 disposed below the upper gate electrodes 130U and/or on the lower gate electrode 130L, and forming an erase transistor used for an erasing operation using the gate induced drain leakage (GIDL) phenomenon. Also, a portion of the gate electrodes 130, for example, memory gate electrodes 130M adjacent to the upper or lower gate electrode 130U and 130L, may be dummy gate electrodes.

The gate electrodes 130 may be vertically stacked and spaced apart from each other, may extend at least in one direction, for example, in the Y-direction, and may form a step difference structure in a staircase shape. The gate electrodes 130 may also be disposed to have a step difference structure in the X-direction. By the step difference structure, the gate electrodes 130 may have regions in which the gate electrode 130 in an upper portion extends longer than the gate electrode 130 in a lower portion, and lower surfaces are exposed downwardly from the interlayer insulating layers 120 and the other gate electrodes 130, respectively, and the regions may be referred to as pad regions 130P. The gate electrodes 130 may be connected to the first cell contact plugs 152 in the pad regions 130P. The gate electrodes 130 may have an increased thickness in the pad regions 130P.

The gate electrodes 130 may include a metal material, such as tungsten (W). According to an example embodiment, the gate electrodes 130 may include polycrystalline silicon or a metal silicide material. In example embodiments, the gate electrodes 130 may further include a diffusion barrier, such as tungsten nitride (WN), tantalum nitride (TaN), titanium nitride (TiN), or a combination thereof.

The interlayer insulating layers 120 may be disposed between the gate electrodes 130. The interlayer insulating layers 120 may also be disposed to be spaced apart from each other in a direction perpendicular to a lower surface of the plate layer 101 and to extend in the Y-direction, similarly to the gate electrodes 130. The interlayer insulating layers 120 may include an insulating material, such as silicon oxide or silicon nitride.

Each of channel structures CH may form a memory cell string and may be spaced apart from each other in rows and columns on a lower surface of plate layer 101. The channel structures CH may be disposed to form a grid pattern on a plan diagram or may be disposed in a zigzag shape in one direction. The channel structures CH have a columnar shape and may have an inclined side surface of which a width decreases toward the plate layer 101 depending on an aspect ratio.

Each of the channel structures CH may have a form in which the first and second channel structures CH1 and CH2 penetrating the lower and upper stack structures of gate electrodes 130, respectively, may be connected to each other, and may have a bent portion due to a difference or change in width in the connection region. However, in example embodiments, the number of the channel structures stacked in the Z-direction may be varied.

Each of the channel structures CH may include a channel layer 140 disposed in the channel hole, a gate dielectric layer 145, a channel filling insulating layer 147, and a channel pad 149. The channel layer 140 may be formed in an annular shape surrounding the channel filling insulating layer 147 therein, or may have a cylindrical shape or a columnar shape without the channel filling insulating layer 147 in example embodiments. The channel layer 140 may include a semiconductor material such as polycrystalline silicon or single crystal silicon. The channel layer 140 may be connected to the plate layer 101 through a first horizontal conductive layer 102 in a lower portion.

The gate dielectric layer 145 may be disposed between the gate electrodes 130 and the channel layer 140. The gate dielectric layer 145 may include a tunneling layer, a charge storage layer, and a blocking layer stacked in order from the channel layer 140. The tunneling layer may tunnel electric charge into the charge storage layer and may include, for example, silicon oxide (SiO₂), silicon nitride (Si₃N₄), silicon oxynitride (SiON), or a combination thereof. The charge storage layer may be a charge trap layer or a floating gate conductive layer. The blocking layer may include, for example, silicon oxide (SiO₂), silicon nitride (Si₃N₄), silicon oxynitride (SiON), a high-κ dielectric material, or a combination thereof. In example embodiments, at least a portion of the gate dielectric layer 145 may extend horizontally along the gate electrodes 130.

The channel pad 149 may be disposed only on an upper end of an upper portion of the second channel structure CH2. The channel pads 149 may include, for example, doped polycrystalline silicon.

The channel layer 140, the gate dielectric layer 145, and the channel filling insulating layers 147 may be connected to each other between the first channel structure CH1 and the second channel structure CH2. An interlayer insulating layer 120 having a relatively great thickness may be further disposed between the first channel structure CH1 and the second channel structure CH2. However, the shape of the interlayer insulating layers 120 may be varied in example embodiments.

The isolation region MS may be disposed to penetrate the gate electrodes 130 and to extend in one direction, for example, in the X-direction. Although only one isolation region is illustrated in FIG. 8, a plurality of isolation regions MS may extend parallel to each other in the Y-direction and may be spaced apart from each other in the X-direction. The isolation region MS may penetrate the entire gate electrodes 130 stacked on the plate layer 101 and may be connected to the plate layer 101.

The isolation region MS may have a shape of which a width decreases toward the plate layer 101 due to a relatively high aspect ratio, but embodiments are not limited thereto. The isolation region MS may include an insulating material, and may include silicon oxide, silicon nitride, or silicon oxynitride, for example.

The first and second cell contact plugs 152 and 154 may extend in the Z-direction and may have an inclined side surface of which a width decreases toward the plate layer 101. Upper ends of the first and second cell contact plugs 152 and 154 may be positioned on a lower surface of the plate layer 101, for example, on the lower surface or in the plate layer 101. The first and second cell contact plugs 152 and 154 may form a portion of a second interconnection structure in the second substrate structure S2.

The first cell contact plugs 152 may electrically connect the gate electrodes 130 to the first interconnection structure 280 in the first substrate structure S1. The first cell contact plugs 152 may be physically and electrically connected to the gate electrodes 130 in the pad regions 130P, respectively, thereby applying an electrical signal to the gate electrodes 130. The first cell contact plugs 152 may penetrate the pad regions 130P of the gate electrodes 130. The first cell contact plugs 152 may penetrate the region in which the gate electrodes 130 form a staircase structure and may extend into the plate layer 101. However, in example embodiments, the first cell contact plugs 152 may not penetrate the gate electrodes 130. In this case, the first cell contact plugs 152 may extend to be connected to a lower surface or a lower portion of each of the gate electrodes 130.

The first cell contact plugs 152 may extend horizontally in the pad regions. The first cell contact plugs 152 may be spaced apart from the gate electrodes 130 above the pad regions by contact insulating layers 125. The contact insulating layers 125 may surround a side surface of one of the first cell contact plugs 152 and may be isolated from each other in the Z-direction. The contact insulating layers 125 may be disposed at substantially the same level as the gate electrodes 130, respectively. The contact insulating layers 125 may include an insulating material, for example, silicon oxide, silicon nitride, or silicon oxynitride.

The second cell contact plugs 154 may be disposed in a region in which the gate electrodes 130 are not disposed, for example, on the external side of the gate electrodes 130. The second cell contact plugs 154 may electrically connect the first to fourth circuit elements TR1 and TR2 of the first substrate structure S1 to external pads. The second cell contact plugs 154 may penetrate a portion of the cell region insulating layer 190 and may extend into the first substrate structure S1.

The first and second cell contact plugs 152 and 154 may include a metal material, for example, tungsten (W), aluminum (Al), copper (Cu), tungsten nitride (WN), tantalum nitride (TaN), titanium nitride (TiN), or a combination thereof.

The cell upper contacts 170 and the cell interconnection lines 180 may form a portion of the second interconnection structure, and may electrically connect the second substrate structure S2 to the first substrate structure S1.

The cell upper contacts 170 may include first to third cell upper contacts 172, 174, and 176, and the cell interconnection lines 180 may include first and second cell interconnection lines 182 and 184. Channel pads 149 and first and second cell contact plugs 152 and 154 may be connected to the first cell upper contacts 172 on a lower end. The first cell upper contacts 172 may be connected to the second cell upper contacts 174 on the lower end, and the second cell upper contacts 174 may be connected to the first cell interconnection lines 182 on the lower end. The third cell upper contacts 176 may vertically connect the first and second cell interconnection lines 182 and 184 to each other. The cell upper contacts 170 may have a cylindrical shape. In example embodiments, the cell upper contacts 170 may have an inclined side surface such a width thereof may decrease toward the plate layer 101 and may increase toward the first substrate structure S1 depending on an aspect ratio.

The first cell interconnection lines 182 may include bitlines connected to the channel structures CH and interconnection lines disposed at the same level as the bitlines. The second cell interconnection lines 184 may be disposed above the first cell interconnection lines 182. The cell interconnection lines 180 may have a line shape extending in at least one direction. In example embodiments, the second cell interconnection lines 184 may have a thickness greater than that of the first cell interconnection lines 182. The cell interconnection lines 180 may have an inclined side surface such that a width thereof decreases toward the plate layer 101.

The cell upper contacts 170 and the cell interconnection lines 180 may include, for example, tungsten (W), aluminum (Al), copper (Cu), tungsten nitride (WN), tantalum nitride (TaN), titanium nitride (TiN), or a combination thereof.

The cell region insulating layer 190 may be disposed to cover an upper surface of the plate layer 101 and gate electrodes 130 on the upper surface of the plate layer 101. The cell region insulating layer 190 may include at least one of an insulating material, for example, silicon oxide, silicon nitride, or silicon carbide, and may include a plurality of insulating layers in example embodiments.

As a circuit for applying voltage to a string select line SSL, a wordline WL, and a ground select line GS_{L} assigned to the gate electrodes 130 in a semiconductor device 100, a pass circuit may be disposed in the first substrate structure S1.

The pass circuit may include a plurality of pass transistors. A low-level voltage or a high-level voltage applied to the string select line SSL, the wordline WL, and the ground select line GS_{L} may be controlled based on a switching operation of the plurality of pass transistors.

The fourth circuit element TR4 may be pass transistors, may receive a high-voltage boosted from third circuit elements forming a feedback loop and may transfer the voltage to each gate electrode 130.

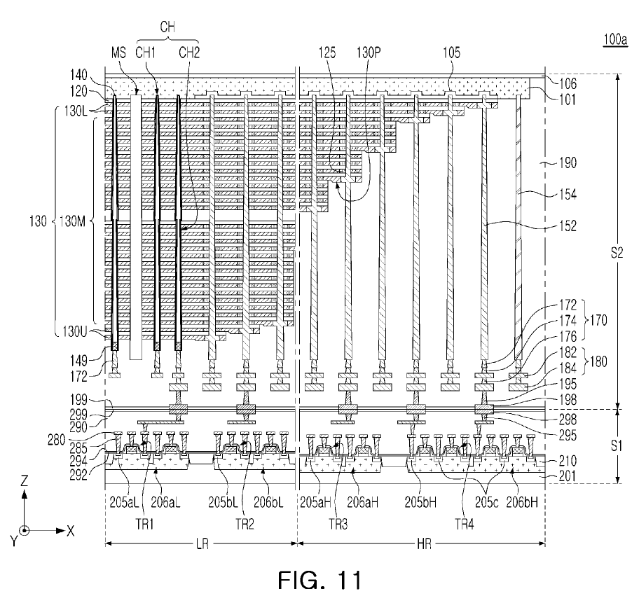

FIG. 11 is a cross-sectional view illustrating a semiconductor device according to example embodiments.

As illustrated in FIG. 11, a semiconductor device 100a may include a first substrate structure S1 including a substrate 201 and a second substrate structure S2 including a plate layer 101. The second substrate structure S2 may be disposed on the first substrate structure S1. In example embodiments, conversely, the second substrate structure S2 may be disposed below the first substrate structure S1.

The description of the first substrate structure S1 described above with reference to FIGS. 8, 9, 10A, and 10B may be applied to the first substrate structure S1. However, the first substrate structure S1 may include a bonding structure including first bonding vias 295, first bonding pads 298, and a first bonding insulating layer 299.

The first bonding vias 295, the first bonding pads 298, and the first bonding insulating layer 299 may be included in a first bonding structure and may be disposed on circuit interconnection lines 280 in an uppermost portion. The first bonding vias 295 may have a cylindrical shape, and the first bonding pads 298 may have a line shape. Upper surfaces of the first bonding pads 298 and upper surfaces of the first bonding insulating layer 299 may be exposed to an upper surface of the first substrate structure S1. The first bonding vias 295 and the first bonding pads 298 may provide an electrical connection path between the first substrate structure S1 and the second substrate structure S2. A portion of the first bonding pads 298 may be disposed only for bonding without being connected to the circuit interconnection lines 280 in a lower portion. The first bonding vias 295 and the first bonding pads 298 may include a conductive material, for example, copper (Cu). The first bonding insulating layer 299 may be disposed around the first bonding pads 298. The first bonding insulating layer 299 may also function as a diffusion barrier for the first bonding pads 298 and may include at least one of, for example, SiN, SiON, SiCN, SiOC, SiOCN, or SiO₂.

In the second substrate structure S2, gate electrodes 130 may be disposed on the lower surface of the plate layer 101.

An upper end of the channel layer 140 may be exposed from the gate dielectric layer 145 on an upper end of the channel structure CH. The upper end of the channel layer 140 may include an upper surface and an upper region of a side surface connected to the upper surface. The upper end of the channel layer 140 may directly contact the plate layer 101 and may be surrounded by the plate layer 101. By this arrangement, the channel layer 140 may be physically and electrically connected to the plate layer 101.

The cover insulating layer 105 may be disposed between the first cell contact plugs 152 and the plate layer 101. The cover insulating layer 105 may cover the upper ends of the first cell contact plugs 152. The cover insulating layer 105 may not extend to the channel structures CH and the second cell contact plug 154. An upper surface of the cover insulating layer 105 may have a curvature along the upper ends of the first cell contact plugs 152, but the shape of an upper surface of the cover insulating layer 105 is not limited thereto. The cover insulating layer 105 may include an insulating material, for example, at least one of silicon oxide, silicon nitride, or silicon carbide. In example embodiments, the cover insulating layer 105 may be spaced apart from each other between the first cell contact plugs 152 and may include a plurality of layers. In example embodiments, the cover insulating layer 105 may be disposed to penetrate the plate layer 101.

The passivation layer 106 may be disposed on an upper surface of the plate layer 101 and may have an opening exposing the input/output pad region IOP. The passivation layer 106 may function as a layer protecting the semiconductor device 100. The passivation layer 106 may include an insulating material, for example, at least one of silicon oxide, silicon nitride, or silicon carbide, and in example embodiments, the passivation layer 106 may include a plurality of insulating layers.

The semiconductor device 100a may include first and second substrate structures S1, S2 bonded to each other vertically.

Second bonding vias 195 of the second bonding structure may be disposed below the second cell interconnection lines 184 and may be connected to the second cell interconnection lines 184, and second bonding pads 198 of the second bonding structure may be connected to the second bonding vias 195. A lower surface of the second bonding pads 198 may be exposed to a lower surface of the second substrate structure S2. The second bonding pads 198 may be bonded and connected to the first bonding pads 298 of the first substrate structure S1, and the second bonding insulating layer 199 may be bonded and connected to the first bonding insulating layer 299 of the first substrate structure S1. The second bonding vias 195 and the second bonding pads 198 may include a conductive material, for example, copper (Cu). The second bonding insulating layer 199 may include at least one of, for example, SiO₂, SiN, SiCN, SiOC, SiON, or SiOCN.

The first and second substrate structures S1 and S2 may be bonded to each other by bonding the first bonding pads 298 to the second bonding pads 198 and by bonding the first bonding insulating layer 299 to the second bonding insulating layer 199. The bonding between the first bonding pads 298 and the second bonding pads 198 may be, for example, copper (Cu)-copper (Cu) bonding, and the bonding between the first bonding insulating layer 299 and the second bonding insulating layer 199 may be, for example, dielectric-dielectric bonding, such as SiCN-SiCN bonding. The first and second substrate structures S1 and S2 may be bonded to each other by hybrid bonding including copper (Cu)-copper (Cu) bonding and dielectric-dielectric bonding.

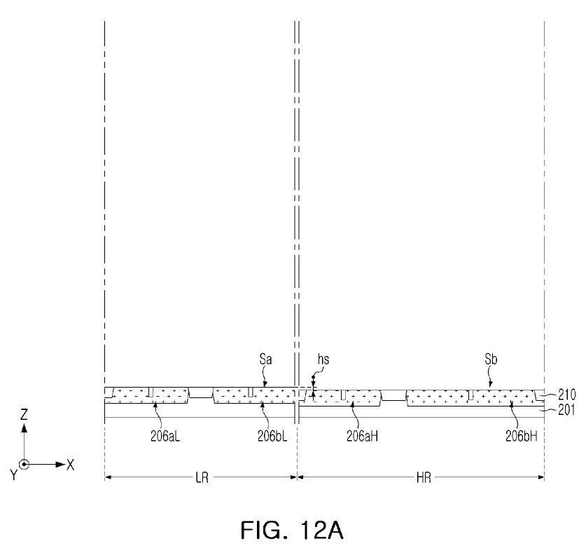

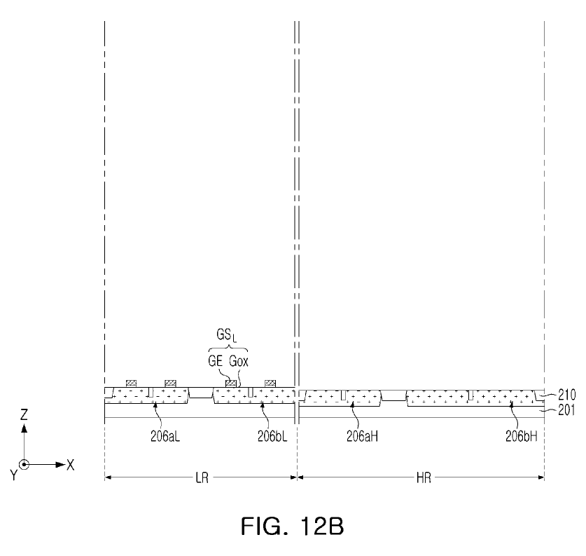

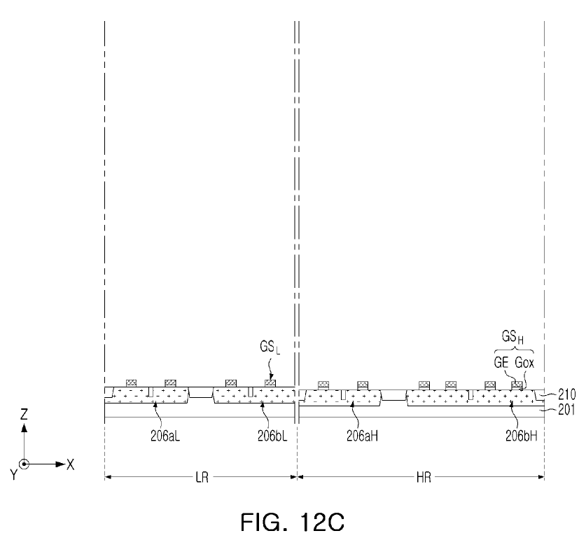

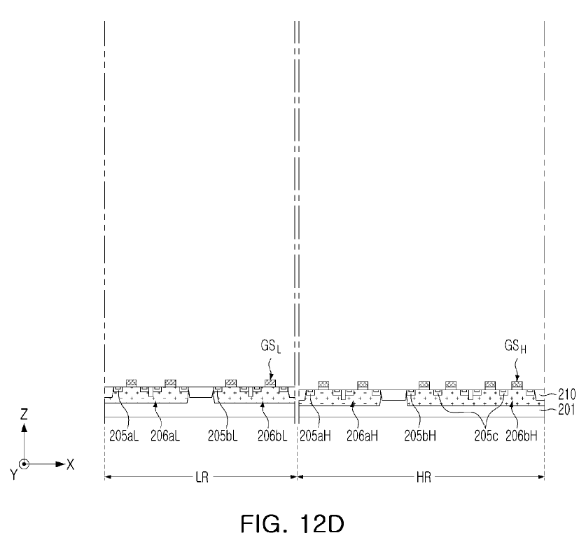

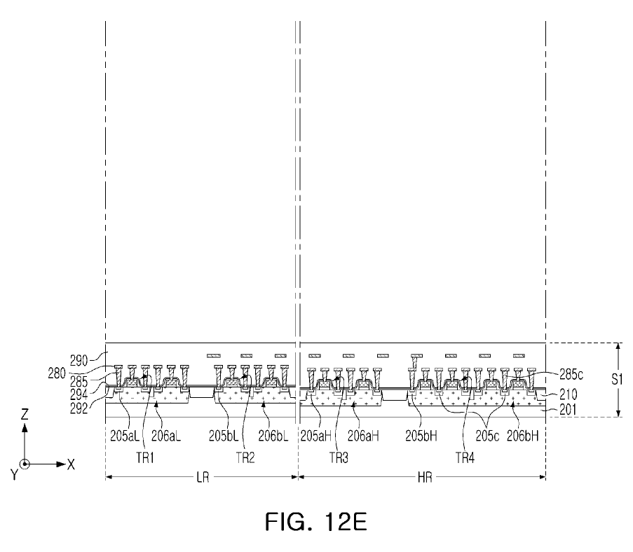

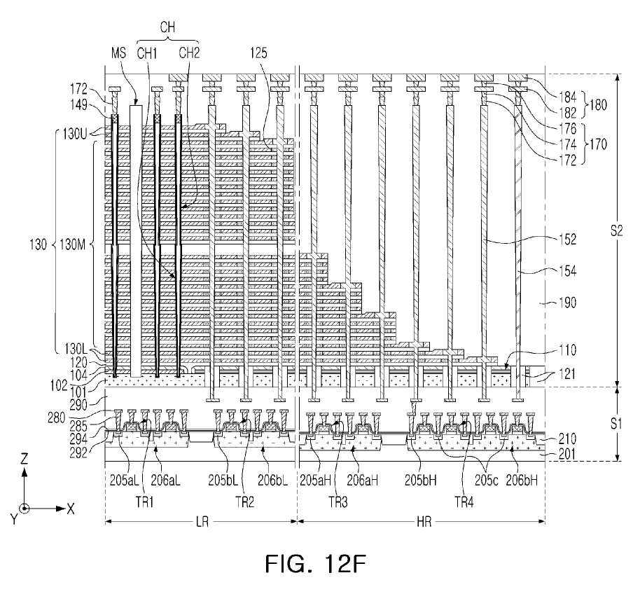

FIGS. 12A, 12B, 12C, 12D, 12E, and 12F are cross-sectional views illustrating a method of manufacturing a semiconductor device according to example embodiments, illustrating a region corresponding to FIG. 8.

Referring to FIG. 12A, a substrate 201 may be prepared.

The substrate 201 may be configured as a semiconductor substrate, for example, a silicon wafer. A region forming a high-voltage element region HR and a low-voltage element region LR may be divided on an upper surface of the substrate 201, and an upper surface of the high-voltage element region HR may be etched to have a substrate step difference hs from an upper surface of the low-voltage element region LR.

Accordingly, the substrate 201 may have a first upper surface Sa in the low-voltage element region LR, and a second upper surface Sb positioned at a level lower than a level of the substrate step difference hs in the high-voltage element region HR.

First well regions 206aL and 206aH may be formed by doping N-type impurities in the regions of the high-voltage element region HR and low-voltage element region LR in which PMOS transistors are disposed, and second well regions 206bL and 206bH may be formed by doping P-type impurities in the regions in which NMOS transistors are disposed. Device isolation regions 210 may be formed, respectively. The device isolation region 210 may be formed by forming a shallow trench and stacking oxides, but embodiments are not limited thereto.

A channel structure may be further formed in the area in which the gate structure GS_{L} is formed on the substrate 201 of the second circuit element TR2 in the low-voltage element region LR. The channel structure may include a semiconductor material having a bandgap smaller than that of the substrate 201 material, and may include silicon-germanium.

Referring to FIG. 12B, a gate dielectric layer Gox and a gate electrode GE for the first and second circuit elements TR1 and TR2 may be formed in the low-voltage element region LR.

A preliminary gate dielectric layer Gox may be deposited in the low-voltage element region LR to include a high-κ material and to have a first thickness t1, and may be formed by depositing hafnium oxide (HfO), but embodiments are not limited thereto. The preliminary gate dielectric layer Gox may be formed by depositing a metal oxide or metal nitride not including other impurities.

The preliminary gate electrode layer GE may be formed on the preliminary gate dielectric layer Gox.

The preliminary gate electrode GE may include a metal silicide, and may be formed by depositing tungsten silicide.

In this case, a silicon-germanium pattern may be formed, as a channel structure, in the lower portion of the preliminary gate dielectric layer Gox in the second circuit element TR2.

By forming a mask layer, the preliminary gate dielectric layer Gox and the preliminary gate electrode GE may be etched, thereby forming the gate structure GS_{L} of the first and second circuit elements TR1 and TR2.

Referring to FIG. 12C, the preliminary gate dielectric layer Gox may be formed on the second upper surface Sb of the substrate 201 in the high-voltage element region HR with a thickness hs the same as the substrate step difference hs. The preliminary gate dielectric layer Gox may be formed to have a relatively great thickness using a material having a low dielectric constant, such as silicon oxide or silicon oxynitride.

The preliminary gate electrode GE may be formed on the preliminary gate dielectric layer Gox, and may be etched, thereby forming the gate structure GS_{H} of the third and fourth circuit elements TR3 and TR4.

In this case, among the etched gate structures GS_{H}, the gate structure GS_{H} of the fourth circuit elements TR4 may have a polygonal shape, for example, a quadrangular shape as illustrated in FIG. 9, and may have an asymmetric structure including the gate protrusion GSp on one end.

Thereafter, referring to FIG. 12D, by performing an ion implantation process using the gate structures GS_{L} and GS_{H} of each of the circuit elements TR1-TR4 as a mask throughout the low-voltage element region LR and the high-voltage element region HR, source/drain regions 205aL 205bL, 205aH and 205bH may be formed in the substrate 201 on both sides of each of the gate structures GS_{L} and GS_{H}. Accordingly, first to fourth circuit elements TR1-TR4 may be completed.

In this case, ion implantation may be performed on the fourth circuit element TR4 to form a common source/drain region 205c, such that the common source/drain region 205c may be formed to be connected to each of the four gate structures GS1-GS4 in the central region of the H-shaped active region.

Referring to FIG. 12E, first and second substrate insulating layers 292 and 294 may be formed in order by covering upper surfaces Sa and Sb of each of the gate structures GS1-GS4 and the substrate 201.

In this case, the first substrate insulating layer 292 may be formed using silicon oxide to have a thickness greater than that of the second substrate insulating layer 294, and may be deposited to have a greater thickness on the side surface of the gate structure GS.

Accordingly, the second substrate insulating layer 294 formed thereafter may be formed of silicon nitride with a uniform thickness.

A portion of a peripheral region insulating layer 290 may be formed on the second substrate insulating layer 294, a portion thereof may be removed by etching, and a conductive material may be buried, thereby forming contact plugs 285. In this case, a common contact plug 285c contacting the protrusion 2d may also be formed. The circuit interconnection lines 280 may be formed, for example, by depositing a conductive material and patterning the material. By this process, a first substrate structure S1 may be prepared.

Thereafter, referring to FIG. 12F, a second substrate structure S2 may be manufactured.

In the second substrate structure S2, sacrificial insulating layers and interlayer insulating layers 120 may be alternately stacked on plate layer 101.

The plate layer 101 may be a semiconductor substrate such as undoped silicon (Si). The sacrificial insulating layers may be layers replaced with the gate electrodes 130 (see FIG. 8) through a subsequent process. The sacrificial insulating layers may be formed of a material etched with etch selectivity with respect to the interlayer insulating layers 120. For example, the interlayer insulating layer 120 may be formed of at least one of silicon oxide or silicon nitride, and the sacrificial insulating layers may be formed of a material different from that of the interlayer insulating layer 120 selected from among silicon, silicon oxide, silicon carbide, or silicon nitride. In example embodiments, the thickness of the interlayer insulating layers 120 and the number of films included therein may be varied from the illustrated example.

Thereafter, by repeatedly performing a photolithography process and an etching process on regions including the ends of the sacrificial insulating layers, a staircase shape may be formed. The sacrificial insulating layers may be formed to have a relatively great thickness on the ends, and processes therefor may be further performed. A portion of the cell region insulating layer 190 covering a lower stack structure of the sacrificial insulating layers and the interlayer insulating layers 120 may be formed.

Vertical sacrificial layers may be formed to correspond to each of the channel structures, and the vertical sacrificial layers may include, for example, polycrystalline silicon.

Channel structures CH penetrating the stack structure of the sacrificial insulating layers and the interlayer insulating layers 120 may be formed.

First, channel holes may be formed by removing vertical sacrificial layers. Thereafter, a gate dielectric layer 145, a channel layer 140, a channel filling insulating layer 147, and a channel pad 149 may be formed in order in each of the channel holes, thereby forming channel structures CH including first and second channel structures CH1 and CH2. The channel layer 140 may be formed on the gate dielectric layer 145 in the channel structures CH. The channel filling insulating layer 147 may be formed to fill the channel structures CH and may be an insulating material. However, in example embodiments, the space between the channel layers 140 may be filled with a conductive material other than the channel filling insulating layer 147. The channel pads 149 may be formed of a conductive material, for example, polycrystalline silicon.

Thereafter, an opening penetrating the sacrificial insulating layers and the interlayer insulating layers 120 and extending to the plate layer 101 may be formed in a region corresponding to the isolation region MS, and sacrificial insulating layers may be removed by supplying an etchant through the opening. The sacrificial insulating layers may be selectively removed, for example, with respect to the interlayer insulating layers 120, using wet etching.

The gate electrodes 130 may be formed by depositing a conductive material in regions from which the sacrificial insulating layers are removed. The conductive material may include a metal, polycrystalline silicon, or a metal silicide material. After the gate electrodes 130 are formed, an insulating material may be deposited in the opening, thereby forming an isolation region MS.

Thereafter, the first cell contact plugs 152 may be formed by depositing a conductive material in the contact holes. When the contact sacrificial layers previously formed in the region in which the contact holes are formed are removed, the insulating material may also be partially removed. In this case, the insulating material may be entirely removed from the pad regions 130P, and the insulating material may remain therebelow and may form the contact insulating layers 125. The first cell contact plugs 152 may be formed to have regions extending horizontally from the pad regions 130P, and may thus be physically and electrically connected to the gate electrodes 130. The second cell contact plug 154 may be formed by forming other contact holes penetrating the cell region insulating layer 190 on the external side of the gate electrodes 130 and extending into the plate layer 101 and depositing a conductive material in the contact holes. The process of depositing the conductive material may be performed simultaneously with the deposition process for the first cell contact plugs 152, but embodiments are not limited thereto.

Second interconnection structures 170 and 180 may be formed on the gate electrodes 130. In the second interconnection structure, cell upper contacts 170 may be formed by etching the cell region insulating layer 190 on the channel pads 149 and the first and second cell contact plugs 152 and 154 and depositing a conductive material. Cell interconnection lines 180 may be formed by a process of depositing and patterning a conductive material, or by forming a portion of the cell region insulating layer 190, patterning the portion, and depositing a conductive material.

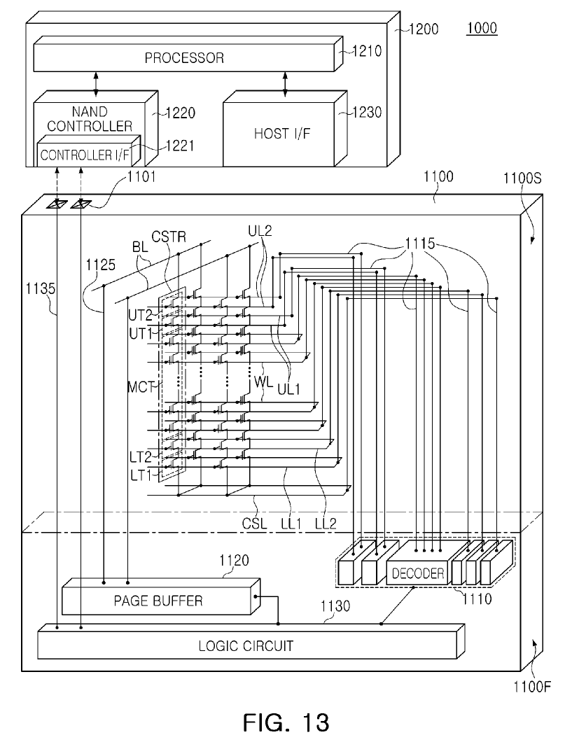

FIG. 13 is a diagram illustrating a data storage system including a semiconductor device according to example embodiments.

Referring to FIG. 13, a data storage system 1000 may include a semiconductor device 1100 and a controller 1200 electrically connected to the semiconductor device 1100. The data storage system 1000 may be implemented as a storage device including one or a plurality of semiconductor devices 1100 or an electronic device including a storage device. For example, the data storage system 1000 may be implemented as a solid state drive device (SSD) including one or a plurality of semiconductor devices 1100, a universal serial bus (USB), a computing system, a medical device, or a communication device.

The semiconductor device 1100 may be implemented as a non-volatile memory device, such as, for example, the NAND flash memory device described in the aforementioned example embodiment with reference to FIGS. 8-11. The semiconductor device 1100 may include a first structure 1100F and a second structure 1100S on the first structure 1100F. In the example embodiments, the first structure 1100F may be disposed on the side of the second structure 1100S. The first structure 1100f may be configured as a peripheral circuit structure including a decoder circuit 1110, a page buffer 1120, and a logic circuit 1130. The second structure 1100S may be configured as a memory cell structure including bitline BL, common source line CSL, wordlines WL, first and second gate upper lines UL1 and UL2, first and second gate lower lines LL1 and LL2, and memory cell strings CSTR between the bitline BL and the common source line CSL.

In the second structure 1100S, each of the memory cell strings CSTR may include a plurality of memory cell transistors MCT disposed between lower transistors LT1 and LT2 adjacent to a common source line CSL, upper transistors UT1 and UT2 adjacent to a bitline BL, and lower transistors LT1 and LT2 and upper transistors UT1 and UT2. The number of lower transistors LT1 and LT2 and the number of upper transistors UT1 and UT2 may be varied in example embodiments.

In example embodiments, the upper transistors UT1 and UT2 may include string select transistors, and the lower transistors LT1 and LT2 may include ground select transistors. The gate lower lines LL1 and LL2 may be configured as gate electrodes of the lower transistors LT1 and LT2, respectively. The wordlines WL may be configured as gate electrodes 130 of the memory cell transistors MCT, and the gate upper lines UL1 and UL2 may be configured as gate electrodes of the upper transistors UT1 and UT2, respectively.

In example embodiments, the lower transistors LT1 and LT2 may include a series-connected lower erase control transistor LT1 and a ground select transistor LT2. The upper transistors UT1 and UT2 may include a string select transistor UT1 and an upper erase control transistor UT2 connected to each other in series. At least one of the lower erase control transistor LT1 and the upper erase control transistor UT2 may be used for an erase operation of erasing data stored in the memory cell transistors MCT using the GIDL phenomenon.

Common source line CSL, first and second gate lower lines LL1 and LL2, wordlines WL, and first and second gate upper lines UL1 and UL2 may be electrically connected to the decoder circuit 1110 through first interconnections 1115 extending from the first structure 1100F to the second structure 1100S. The bitlines BL may be electrically connected to the page buffer 1120 through the second interconnections 1125 extending from the first structure 1100F to the second structure 1100S.

In the first structure 1100F, the decoder circuit 1110 and the page buffer 1120 may perform a control operation for at least one select memory cell transistor among a plurality of memory cell transistors MCT. The decoder circuit 1110 and the page buffer 1120 may be controlled by the logic circuit 1130. The semiconductor device 1100 may communicate with the controller 1200 through an input/output pad 1101 electrically connected to the logic circuit 1130. The input/output pad 1101 may be electrically connected to the logic circuit 1130 through an input/output interconnection 1135 extending from the first structure 1100F to the second structure 1100S.

The controller 1200 may include a processor 1210, a NAND controller 1220, and a host interface 1230. In example embodiments, the data storage system 1000 may include a plurality of semiconductor devices 1100, and in this case, the controller 1200 may control a plurality of semiconductor devices 1100.

The processor 1210 may control operations of the data storage system 1000 including the controller 1200. The processor 1210 may operate according to predetermined firmware and may access the semiconductor devices 1100 by controlling the NAND controller 1220. The NAND controller 1220 may include a controller interface 1221 handling communication with the semiconductor device 1100. Through the controller interface 1221, control commands for controlling the semiconductor device 1100, data to be written in the memory cell transistors MCT of the semiconductor device 1100, data to be read from the memory cell transistors MCT of the semiconductor device 1100, or the like, may be transmitted. The host interface 1230 may provide a communication function between the data storage system 1000 and an external host. When a control command is received from an external host through the host interface 1230, the processor 1210 may control the semiconductor device 1100 in response to the control command.

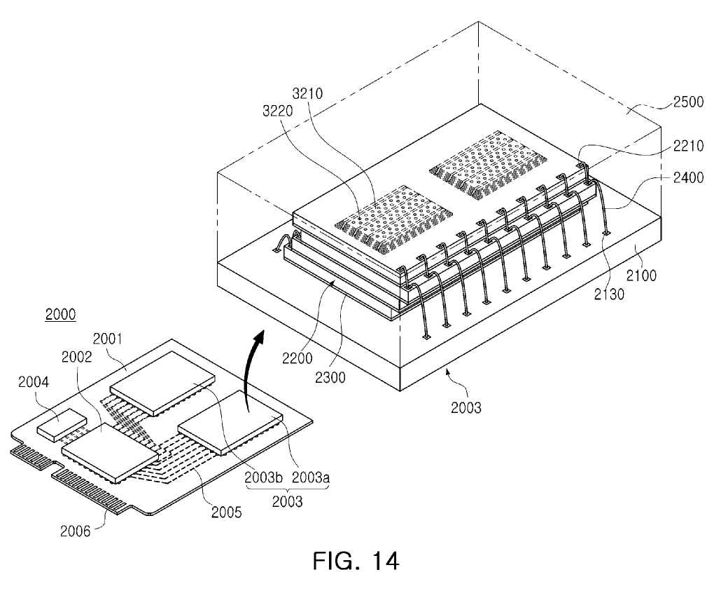

FIG. 14 is a perspective diagram illustrating a data storage system including a semiconductor device according to example embodiments of the present disclosure.

Referring to FIG. 14 a data storage system 2000 in an example embodiment may include a main board 2001, a controller 2002 mounted on the main board 2001, one or more semiconductor packages 2003, and a dynamic random access memory (DRAM) 2004. The semiconductor package 2003 and the DRAM 2004 may be connected to the controller 2002 by interconnection patterns 2005 formed on the main board 2001.

The main board 2001 may include a connector 2006 including a plurality of pins coupled to an external host. The number and arrangement of the plurality of pins in the connector 2006 may be varied depending on a communication interface between the data storage system 2000 and the external host. In the example embodiments, the data storage system 2000 may communicate with an external host according to one of interfaces from among universal serial bus (USB), peripheral component interconnect express (PCI-Express), serial advanced technology attachment (SATA), M-Phy for universal flash storage (UFS). In the example embodiments, the data storage system 2000 may operate by power supplied from an external host through the connector 2006. The data storage system 2000 may further include a power management integrated circuit (PMIC) for distributing power supplied from the external host to the controller 2002 and the semiconductor package 2003.

The controller 2002 may write data to or may read data from the semiconductor package 2003, and may improve an operating speed of the data storage system 2000.

The DRAM 2004 may be configured as a buffer memory for alleviating a difference in speeds between the semiconductor package 2003, which is a data storage space, and an external host. The DRAM 2004 included in the data storage system 2000 may operate as a cache memory, and may provide a space for temporarily storing data in a control operation for the semiconductor package 2003. When the data storage system 2000 includes the DRAM 2004, the controller 2002 may further include a DRAM controller for controlling the DRAM 2004 in addition to the NAND controller for controlling the semiconductor package 2003.

The semiconductor package 2003 may include first and second semiconductor packages 2003a and 2003b spaced apart from each other. Each of the first and second semiconductor packages 2003a and 2003b may be configured as a semiconductor package including a plurality of semiconductor chips 2200. Each of the first and second semiconductor packages 2003a and 2003b may include a package substrate 2100, semiconductor chips 2200 on the package substrate 2100, adhesive layers 2300 disposed on lower surfaces of the semiconductor chips 2200, respectively, a bonding structure 2400 electrically connecting the semiconductor chips 2200 to the package substrate 2100, and a molding layer 2500 covering the semiconductor chips 2200 and the bonding structure 2400 on the package substrate 2100.

The package substrate 2100 may be configured as a printed circuit board including package upper pads 2130. Each semiconductor chip 2200 may include an input/output pad 2210. The input/output pad 2210 may correspond to the input/output pad 1101 in FIG. 13. Each of the semiconductor chips 2200 may include gate stack structures 3210 and channel structures 3220. Each of the semiconductor chips 2200 may include the semiconductor device described in the aforementioned example embodiment with reference to FIGS. 8-11.

In the example embodiments, the bonding structure 2400 may be configured as a bonding wire electrically connecting the input/output pad 2210 to the upper package pads 2130. Accordingly, in each of the first and second semiconductor packages 2003a and 2003b, the semiconductor chips 2200 may be electrically connected to each other by a bonding wire method, and may be electrically connected to the upper package pads 2130 of the package substrate 2100. In the example embodiments, in each of the first and second semiconductor packages 2003a and 2003b, the semiconductor chips 2200 may be electrically connected to each other by a connection structure including a through-electrode (TSV) instead of the bonding structure 2400 of a bonding wire method.

In example embodiments, the controller 2002 and the semiconductor chips 2200 may be included in a single package. In an example embodiment, the controller 2002 and the semiconductor chips 2200 may be mounted on an interposer substrate different from the main board 2001, and the controller 2002 and the semiconductor chips 2200 may be connected to each other by interconnection formed on the interposer substrate.

According to example embodiments of the present disclosure, a method of manufacturing a semiconductor device includes forming a device isolation region defining a bar-type active region on a substrate, forming a gate dielectric layer on the active region, forming a gate electrode layer on the gate dielectric layer, forming a first gate structure and a second gate structure spaced apart from each other in a first direction by patterning the gate electrode layer and the gate dielectric layer, and forming individual source/drain regions on one side of the first and second gate structures and a common source/drain region between the first and second gate structures in the active region by implanting impurities using the first and second gate structures as masks, where the common source/drain region includes a protrusion protruding to one side, and where each of the first gate structure and the second gate structure is formed to include a gate protrusion protruding toward a protrusion.

The gate protrusion may be patterned to be spaced apart from the protrusion on a plane.

The common source/drain region may include a bent portion by a difference in lengths between the body portion and the protrusion in the bar-type active region, and the gate protrusion may protrude toward the bent portion.

Each of the first gate structure and the second gate protrusion may be patterned to include a base portion disposed on the bar-type active region, extended portions extending in the second direction from both sides of the base portion, and the gate protrusion protruding in the first direction from at least one extended portion of the extended portions.

At least a portion of the gate protrusion may be patterned to be disposed on the device isolation region.

The gate protrusion may be patterned to be spaced apart from the body portion on a plane.

The gate protrusion may be patterned to contact the bent portion on a plane.

The gate protrusion may be patterned to include a first portion overlapping the body portion, and a second portion extending with the first portion and overlapping the device isolation region.

The gate protrusion of the first gate structure and the gate protrusion of the second gate structure may be patterned to be symmetrically disposed with respect to the protrusion.

The method may further include forming a contact plug contacting the protrusion.

According to the aforementioned example embodiments, when transistors are implemented to be connected to each other in series and parallel and to share a source or drain region, and the contact region of the shared active region is bent and protrudes, a portion of the gate structure may be disposed to protrude in proximity to the bend region, thereby preventing currents flowing from the contact region from being concentrated in the bend region.

Accordingly, when a high-level drain voltage is applied to the shared active region, the turn-on current due to the high voltage may spread and flow in the bend region due to the electric field caused by the high-level gate voltage of the adjacent gate structure. Accordingly, the turn-on current of the transistors may increase, thereby improving element reliability of the transistor.

Also, when the transistor is turned off, holes may be concentrated in the bend region, which may have the same effect as forming a depletion region with electrons in the bend region when turned on. Accordingly, the resistance of the shared active region in a turn-off state may be increased, such that the off-current may be further reduced, thereby further improving element reliability.

The transistors may be applied as pass transistors configured to apply a high voltage in the peripheral circuit region which drives the cell structure, thereby transferring a large current to the corresponding contact plug when turn on, and as an off-current may not be generated when turned off, element reliability may be ensured.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A semiconductor device, comprising:
a substrate;
a first gate structure and a second gate structure on the substrate and spaced apart from each other in a first direction;
a first source/drain region on one side of the first gate structure;
a second source/drain region on one side of the second gate structure; and
a common source/drain region between the first gate structure and the second gate structure,
wherein the common source/drain region comprises:
a body portion having a first length in the first direction between the first gate structure and the second gate structure and a first width in a second direction intersecting the first direction, and
a protrusion protruding from one side of the body portion and having a second length in the first direction that is less than the first length, and
wherein at least one of the first gate structure and the second gate structure comprises:
a base region between the body portion and at least one of the first source/drain region and the second source/drain region; and
a gate protrusion protruding from the base region toward the protrusion.

2. The semiconductor device of claim 1, wherein the gate protrusion is spaced apart from the protrusion in plan view.

3. The semiconductor device of claim 1, wherein the gate protrusion is spaced apart from the body portion in plan view.

4. The semiconductor device of claim 1, wherein the gate protrusion is offset from the common source/drain region in a third direction perpendicular to an upper surface of the substrate.

5. The semiconductor device of claim 1, wherein the common source/drain region comprises a bent portion between the body portion and the protrusion, and
wherein the gate protrusion protrudes toward the bent portion.

6. The semiconductor device of claim 5, wherein the gate protrusion contacts the bent portion in plan view.

7. The semiconductor device of claim 1, further comprising:
a device isolation layer surrounding the first source/drain region, the second source/drain region and the common source/drain region,
wherein at least a portion of the gate protrusion is on the device isolation layer.

8. The semiconductor device of claim 7, wherein the gate protrusion comprises a first portion overlapping the body portion, and a second portion extending from the first portion and overlapping the device isolation layer.

9. The semiconductor device of claim 8, wherein, in the second direction a width of the first portion is equal to a width of the second portion.

10. The semiconductor device of claim 1, wherein each of the first gate structure and the second gate structure comprises a gate protrusion, and
wherein the gate protrusion of the first gate structure and the gate protrusion of the second gate structure are the same.

11. The semiconductor device of claim 1, wherein each of the first gate structure and the second gate structure comprises a gate protrusion, and
wherein the gate protrusion of the first gate structure and the gate protrusion of the second gate structure are symmetrically disposed with respect to the protrusion.

12. The semiconductor device of claim 1, wherein each of the first gate structure and the second gate structure includes:
a base portion having the first width in the second direction and aligned with the common source/drain region in the first direction; and
extended portions extending from both sides of the base portion in the second direction; and
wherein the gate protrusion protrudes in the first direction from at least one of the extended portions.

13. The semiconductor device of claim 12, wherein the gate protrusion comprises a first side gate protrusion protruding in the first direction from a first extended portion of the extended portions, and a second side gate protrusion protruding in the first direction from a second extended portion of the extended portions.

14. The semiconductor device of claim 1, wherein each of the first gate structure and the second gate structure comprise:
a gate dielectric layer between the common source/drain region and at least one of the first source/drain region and the second source/drain region; and
a gate electrode on the gate dielectric layer, and
wherein the gate electrode comprises tungsten silicide.

15. The semiconductor device of claim 1, further comprising:
a contact plug on the protrusion and configured to apply a voltage to the common source/drain region.

16. A semiconductor device, comprising:
a cell structure comprising cell gate electrodes, channel structures penetrating the cell gate electrodes, and contact plugs connected to the cell gate electrodes; and
a peripheral circuit structure connected to the cell structure, and comprising a substrate comprising a first element region and a second element region, first circuit elements in the first element region and having a first conductivity-type, second circuit elements in the first element region and having a second conductivity-type different from the first conductivity-type, third circuit elements in the second element region and having the first conductivity-type, and fourth circuit elements in the second element region and having the second conductivity-type,
wherein each of the first circuit elements and the second circuit elements comprises a gate structure comprising a gate dielectric layer on the substrate, and a gate electrode on the gate dielectric layer,
wherein each of the fourth circuit elements comprises:
a first gate structure and a second gate structure on the substrate and spaced apart from each other in a first direction;
individual source/drain regions on external sides of the first gate structure and the second gate structure in the first direction; and
a common source/drain region between the first gate structure and the second gate structure,
wherein the common source/drain region comprises a body portion aligned with the individual source/drain regions in the first direction and a protrusion protruding from one side of the body portion between the first gate structure and the second gate structure, and
wherein each of first gate structure and the second gate structure comprises a gate protrusion protruding toward the protrusion in the first direction and spaced apart from the protrusion in the first direction.

17. The semiconductor device of claim 16, wherein the semiconductor device further comprises a contact plug connected to the protrusion.

18. The semiconductor device of claim 16, wherein the fourth circuit elements are configured as pass circuits configured to apply a voltage to the cell gate electrodes.

19. The semiconductor device of claim 16, wherein a drive voltage of the first circuit elements and the second circuit elements in the first element region is less than a drive voltage of the third circuit elements and the fourth circuit elements in the second element region.

20. A data storage system, comprising:
a semiconductor storage device comprising a first substrate structure comprising a substrate, first circuit elements on the substrate and driven by a first drive voltage and second circuit elements on the substrate driven by a second drive voltage greater than the first drive voltage, a second substrate structure comprising channel structures and gate electrodes, and an input/output pad connected to the first circuit elements and the second circuit elements; and
a controller connected to the semiconductor storage device through the input/output pad and configured to control the semiconductor storage device,
wherein each of the second circuit elements comprises:
a first gate structure and a second gate structure on the substrate and spaced apart from each other in a first direction;
individual source/drain regions on an external side of the first gate structure and the second gate structure in the first direction; and
a common source/drain region between the first gate structure and the second gate structure,
wherein the common source/drain region comprises a body portion aligned with the individual source/drain regions in the first direction and a protrusion protruding from one side of the body portion, between the first gate structure and the second gate structure, and
wherein each of the first gate structure and the second gate structure comprises a gate protrusion protruding toward the protrusion in the first direction.
